(19) United States
(12) Patent Application Publication
(10) Pub. No.: US 2025/0048614 A1
(43) Pub. Date: Feb. 6, 2025

(54) MICROELECTRONIC DEVICES AND MEMORY DEVICES INCLUDING VERTICALLY SPACED TRANSISTORS AND STORAGE DEVICES, AND RELATED ELECTRONIC SYSTEMS

(71) Applicant: Micron Technology, Inc., Boise, ID (US)

(72) Inventors: Fatma Arzum Simsek-Ege, Bose, ID (US); David A. Daycock, Boise, ID (US); Christopher K. Morzano, Boise, ID (US)

(21) Appl. No.: 18/745,962

(22) Filed: Jun. 17, 2024

Related U.S. Application Data
(60) Provisional application No. 63/516,823, filed on Jul. 31, 2023.

(51) Int. Cl. H10B 12/00

(52) U.S. Cl. CPC H10B 12/00

(57) ABSTRACT

A microelectronic device comprises a first transistor structure comprising multiple vertical levels of channel regions, a second transistor structure neighboring the first transistor structure and comprising additional multiple vertical levels of channel regions, a storage device vertically overlying the first transistor structure and the second transistor structure, a first conductive contact structure contacting the first transistor structure, and a second conductive contact structure contacting the second transistor structure. Related memory devices and electronic systems are also described.

### CROSS-REFERENCE TO RELATED APPLICATION

This application claims the benefit under 35 U.S.C. § 119 (e) of U.S. Provisional Patent Application Ser. No. 63/516,823, filed Jul. 31, 2023, the disclosure of which is hereby incorporated herein in its entirety by this reference.

### TECHNICAL FIELD

The disclosure, in various embodiments, relates generally to the field of microelectronic device design and fabrication. More specifically, the disclosure relates to microelectronic devices including memory cells individually comprising vertically spaced transistors and storage devices, and to related memory devices and electronic systems.

### BACKGROUND

Microelectronic device designers often desire to increase the level of integration or density of features within a microelectronic device by reducing the dimensions of the individual features and by reducing the separation distance between neighboring features. In addition, microelectronic device designers often seek to design architectures that are not only compact, but offer performance advantages, as well as simplified designs.

One example of a semiconductor device is a memory device. Memory devices are generally provided as internal integrated circuits in computers or other electronic devices. There are many types of memory including, but not limited to, random-access memory (RAM), read only memory (ROM), dynamic random-access memory (DRAM), synchronous dynamic random-access memory (SDRAM), flash memory, and resistance variable memory. Non-limiting examples of resistance variable memory include resistive random-access memory (RRAM), conductive bridge random-access memory (conductive bridge RAM), magnetic random-access memory (MRAM), phase change material (PCM) memory, phase change random-access memory (PCRAM), spin-torque-transfer random-access memory (STTRAM), oxygen vacancy-based memory, and programmable conductor memory.

A typical memory cell of a memory device includes one access device, such as a transistor, and one memory storage structure, such as a capacitor. Modern applications for semiconductor devices can employ significant quantities of memory cells, arranged in memory arrays exhibiting rows and columns of the memory cells. The memory cells may be electrically accessed through digit lines (e.g., bit lines, data lines) and word lines (e.g., access lines) arranged along the rows and columns of the memory cells of the memory arrays. Memory arrays can be two-dimensional (2D) so as to exhibit a single deck (e.g., a single tier, a single level) of the memory cells, or can be three-dimensional (3D)) so as to exhibit multiple decks (e.g., multiple levels, multiple tiers) of the memory cells.

To improve the operating parameters of the memory cell, some have formed so-called two transistor-one capacitor memory cells wherein the storage device is in communication with two transistors, and some have desired to increase the capacitance of the storage device. However, increasing the number of transistors for each memory cell undesirably increases the area occupied by the memory cells and decreases the packing density of the memory cells of the array. In addition, increasing the capacitance of the storage device increases the area occupied by the memory cell.

### BRIEF DESCRIPTION OF THE DRAWINGS

FIG. 1A through FIG. 1V are simplified, partial top-down view (FIG. 1A, FIG. 1E, FIG. 1G, FIG. 1L, and FIG. 1T) and simplified, partial cross-sectional views (FIG. 1B through FIG. 1D, FIG. 1F, FIG. 1H through FIG. 1K, FIG. 1M through FIG. 1S, and FIG. 1U through FIG. 1V) illustrating a method of forming a microelectronic device, in accordance with embodiments of the disclosure.

FIG. 2 is a block diagram of an electronic system, in accordance with embodiments of the disclosure.

### DETAILED DESCRIPTION

The illustrations included herewith are not meant to be actual views of any particular systems, microelectronic structures, microelectronic devices, or integrated circuits thereof, but are merely idealized representations that are employed to describe embodiments herein. Elements and features common between figures may retain the same numerical designation except that, for ease of following the description, reference numerals begin with the number of the drawing on which the elements are introduced or most fully described.

The following description provides specific details, such as material types, material thicknesses, and processing conditions in order to provide a thorough description of embodiments described herein. However, a person of ordinary skill in the art will understand that the embodiments disclosed herein may be practiced without employing these specific details. Indeed, the embodiments may be practiced in conjunction with conventional fabrication techniques employed in the semiconductor industry. In addition, the description provided herein does not form a complete process flow for manufacturing a microelectronic device (e.g., a semiconductor device, a memory device, such as DRAM memory device), apparatus, memory device, or electronic system, or a complete microelectronic device, apparatus, memory device, or electronic system including conductive contact structures. The structures described below do not form a complete microelectronic device, apparatus, memory device, or electronic system. Only those process acts and structures necessary to understand the embodiments described herein are described in detail below. Additional acts to form a complete microelectronic device, apparatus, memory device, or electronic system from the structures may be performed by conventional techniques.

Drawings presented herein are for illustrative purposes only and are not meant to be actual views of any particular material, component, structure, device, or system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, the term “memory device” means and includes microelectronic devices exhibiting memory functionality, but not necessarily limited to memory functionality. Stated another way, and by way of example only, the term “memory device” means and includes not only conventional memory (e.g., conventional volatile memory, such as conventional dynamic random-access memory (DRAM); conventional non-volatile memory, such as conventional NAND memory), but also includes an application specific integrated circuit (ASIC) (e.g., a system on a chip (SoC)), a microelectronic device combining logic and memory, and a graphics processing unit (GPU) incorporating memory.

As used herein, the term “configured” refers to a size, shape, material composition, orientation, and arrangement of one or more of at least one structure and at least one apparatus facilitating operation of one or more of the structure and the apparatus in a predetermined way.

As used herein, the terms “vertical,” “longitudinal,” “horizontal,” and “lateral” are in reference to a major plane of a structure and are not necessarily defined by earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the figures, a “horizontal” or “lateral” direction may be perpendicular to an indicated “Z” axis and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, features (e.g., regions, materials, structures, devices) described as “neighboring” one another means and includes features of the disclosed identity (or identities) that are located most proximate (e.g., closest to) one another. Additional features (e.g., additional regions, additional materials, additional structures, additional devices) not matching the disclosed identity (or identities) of the “neighboring” features may be disposed between the “neighboring” features.

As used herein, spatially relative terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of”′ other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped, etc.) and the spatially relative descriptors used herein interpreted accordingly.

As used herein, the singular forms “a,” “an,” and “the” are intended to include the plural forms as well, unless the context clearly indicates otherwise.

As used herein, “and/or” includes any and all combinations of one or more of the associated listed items.

As used herein, the phrase “coupled to” refers to structures operatively connected with each other, such as electrically connected through a direct Ohmic connection or through an indirect connection (e.g., by way of another structure).

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions. In addition, an “insulative structure” means and includes a structure formed of and including an insulative material.

Unless the context indicates otherwise, the materials described herein may be formed by any suitable technique including, but not limited to, spin coating, blanket coating, chemical vapor deposition (CVD), plasma enhanced CVD (PECVD), atomic layer deposition (ALD), plasma enhanced ALD (PEALD), physical vapor deposition (PVD) (e.g., sputtering), or epitaxial growth.

According to embodiments described herein, an array of memory cells includes memory cells, each individually comprising two transistors and one storage device (e.g., two transistor-one capacitor (2T-1C)) memory cells. The memory cells may individually comprise the storage device vertically spaced from the transistors. The transistors may be vertically spaced from one another. In some such embodiments, a second vertical transistor of a memory cell may be located within the horizontal boundaries of a first vertical transistor of the memory cell. The first transistor and the second transistor may be in electrical communication with an electrode of the storage device. In some embodiments, the first transistor and the second transistor are in electrical communication with different electrodes of the storage device. In some embodiments, each of the first transistor and the second transistor comprise multiple vertical levels of channel regions vertically spaced from one another. The storage device may vertically overlie the transistors and may include multiple levels of electrode materials and dielectric materials. The multiple levels of the electrode materials and dielectric materials may facilitate increasing the capacitance of the storage device compared to storage devices formed within a single vertical plane.

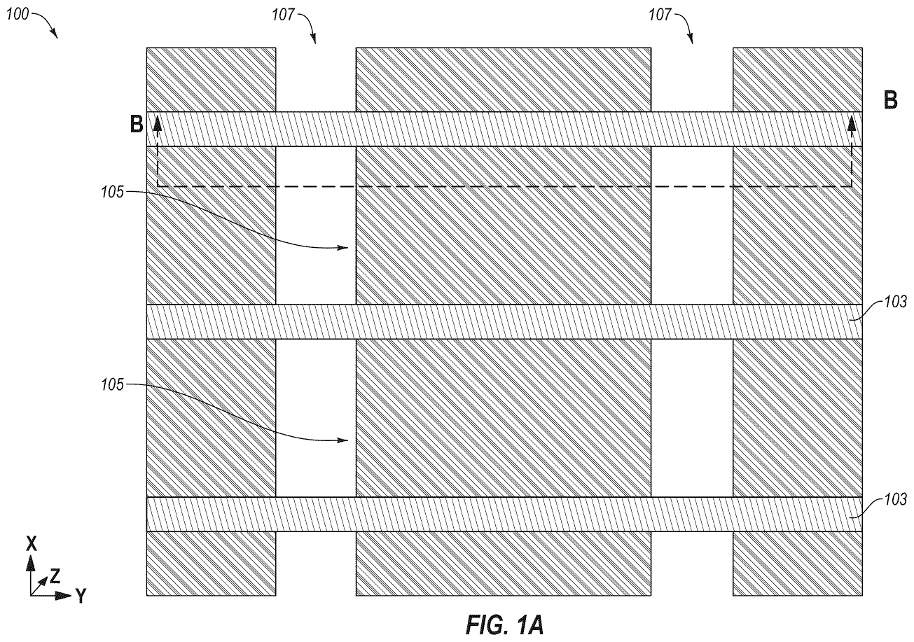

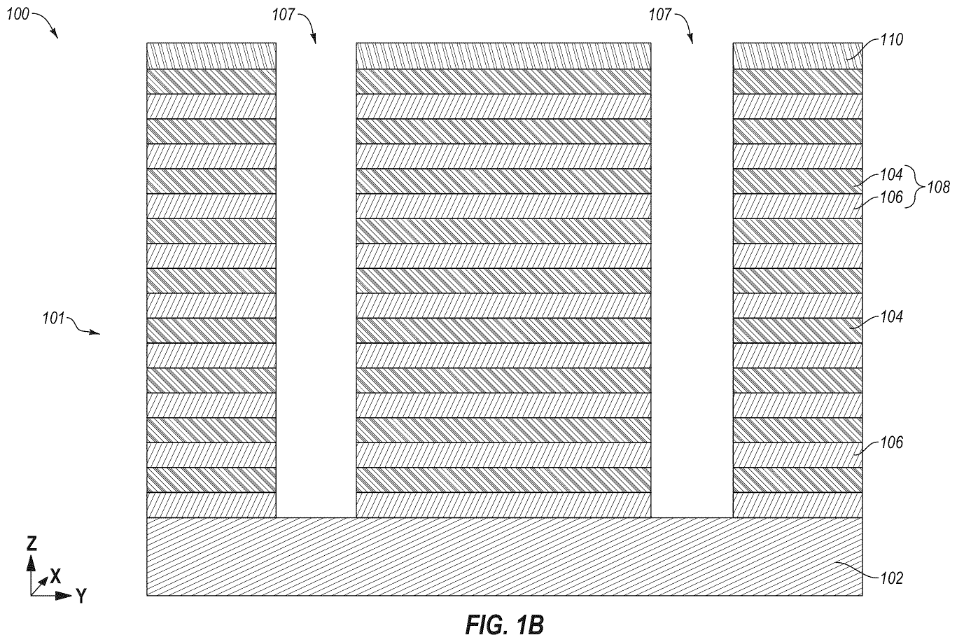

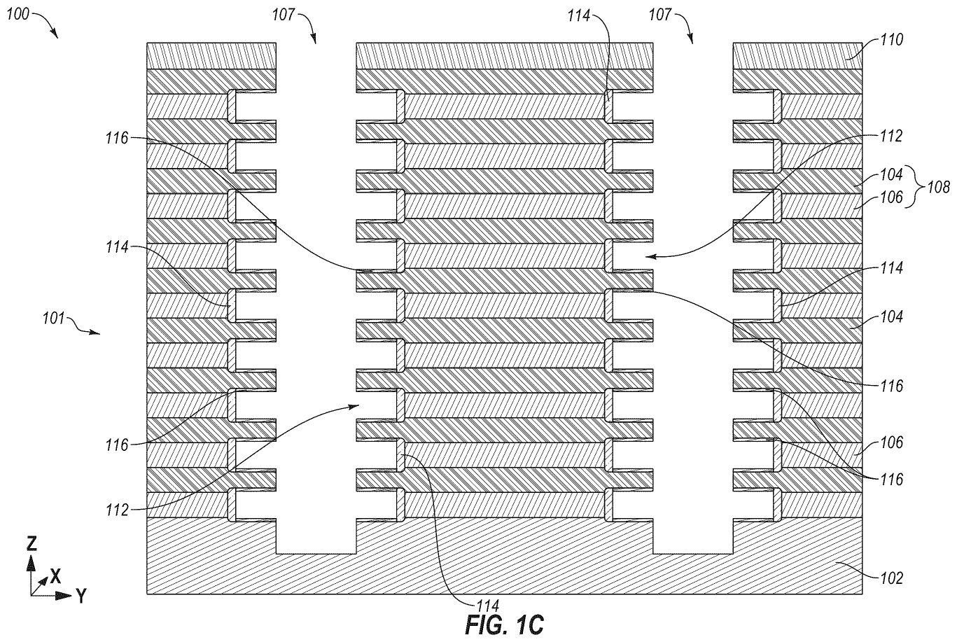

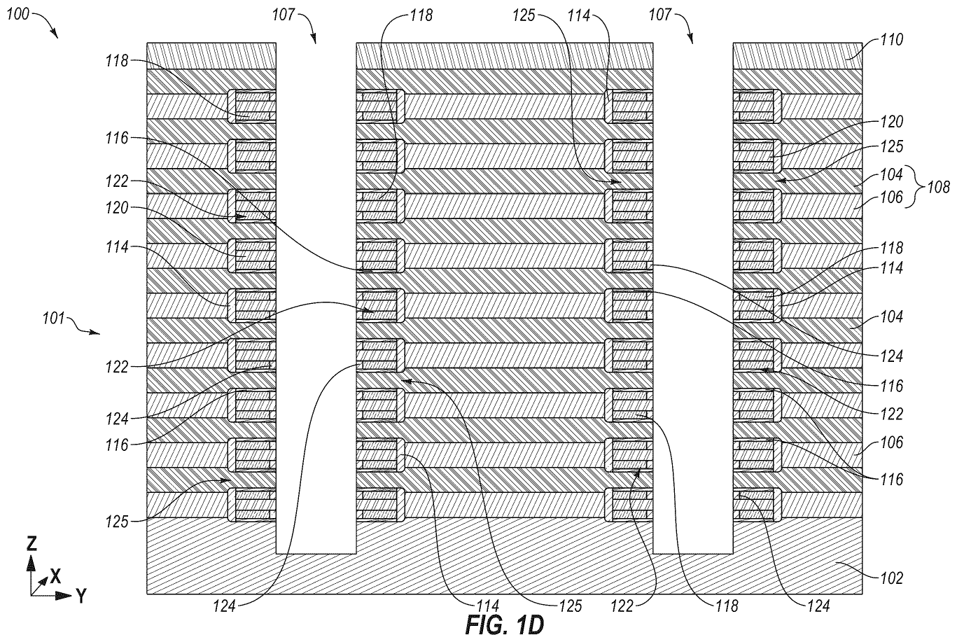

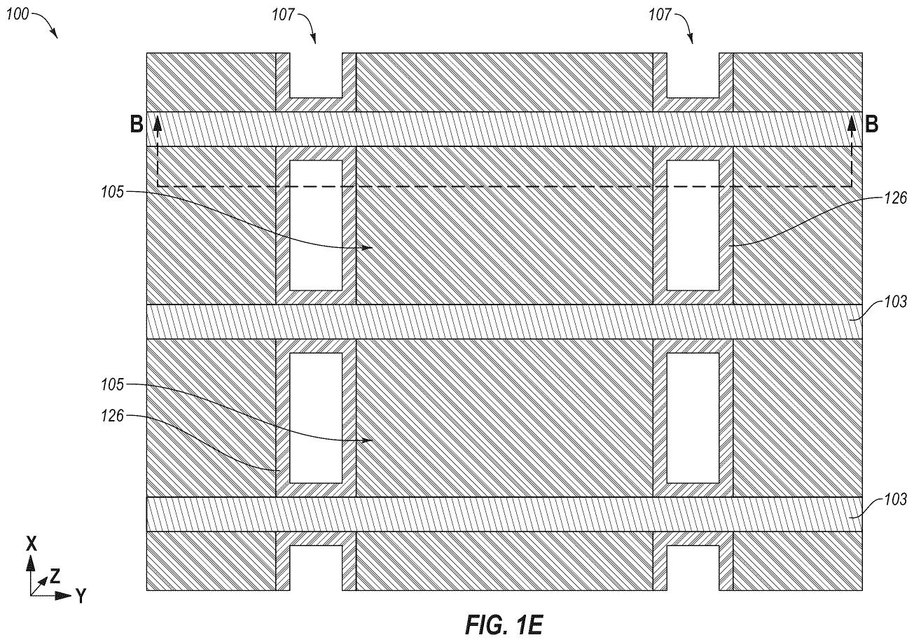

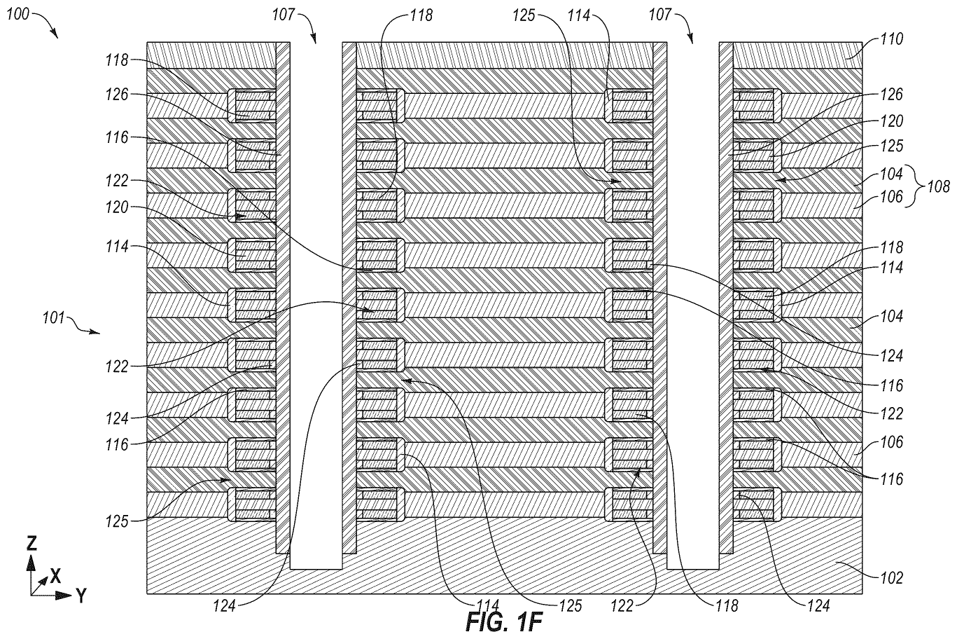

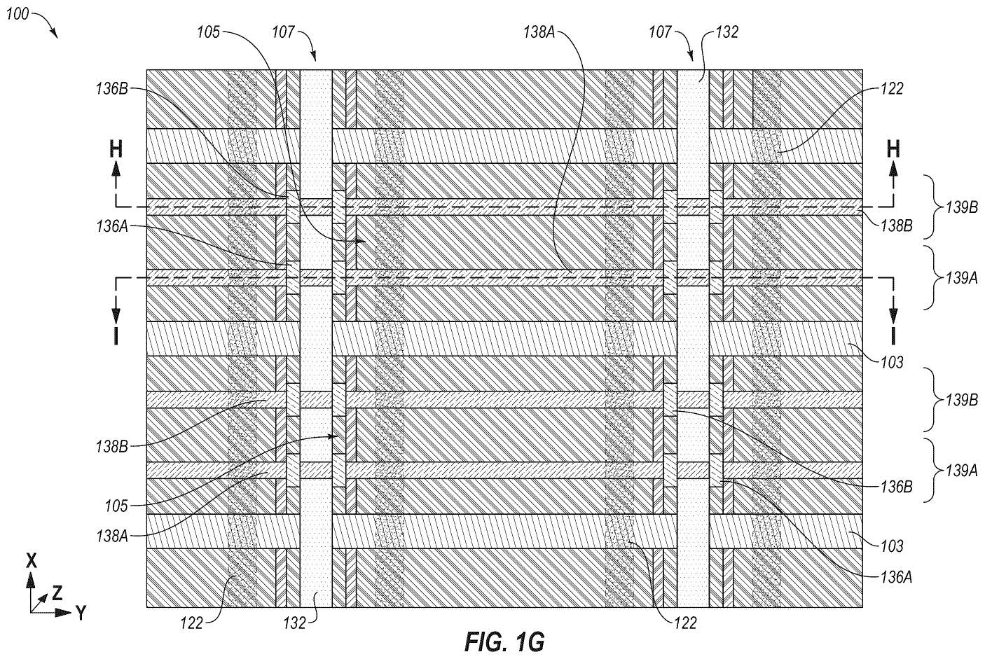

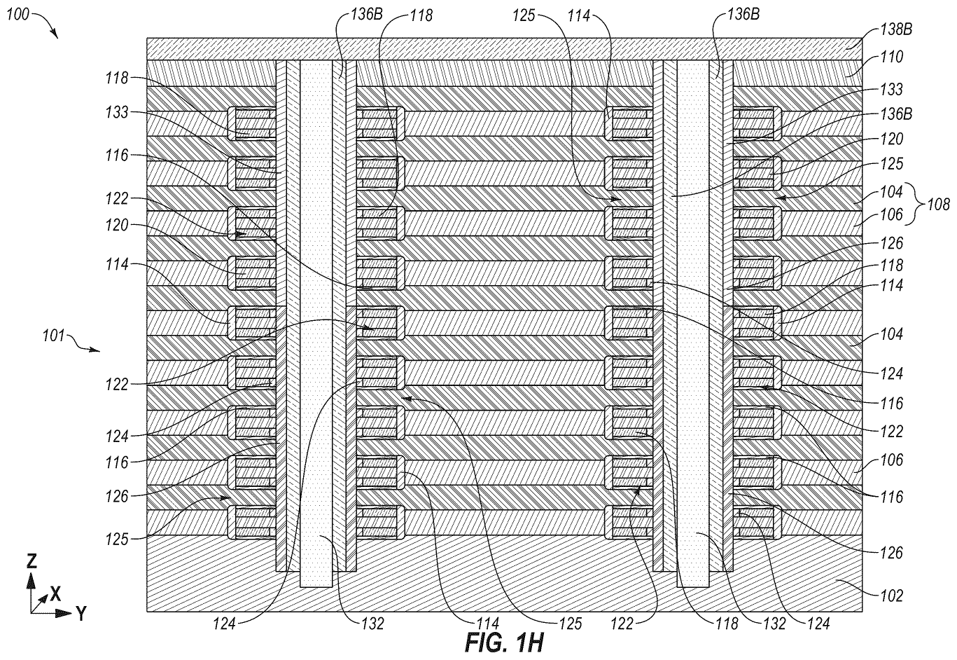

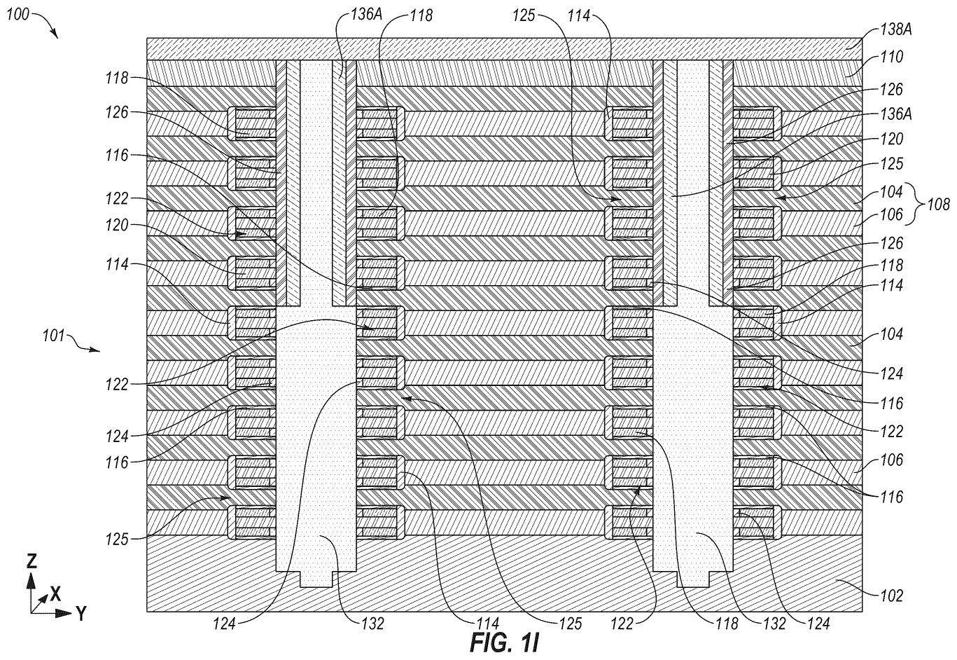

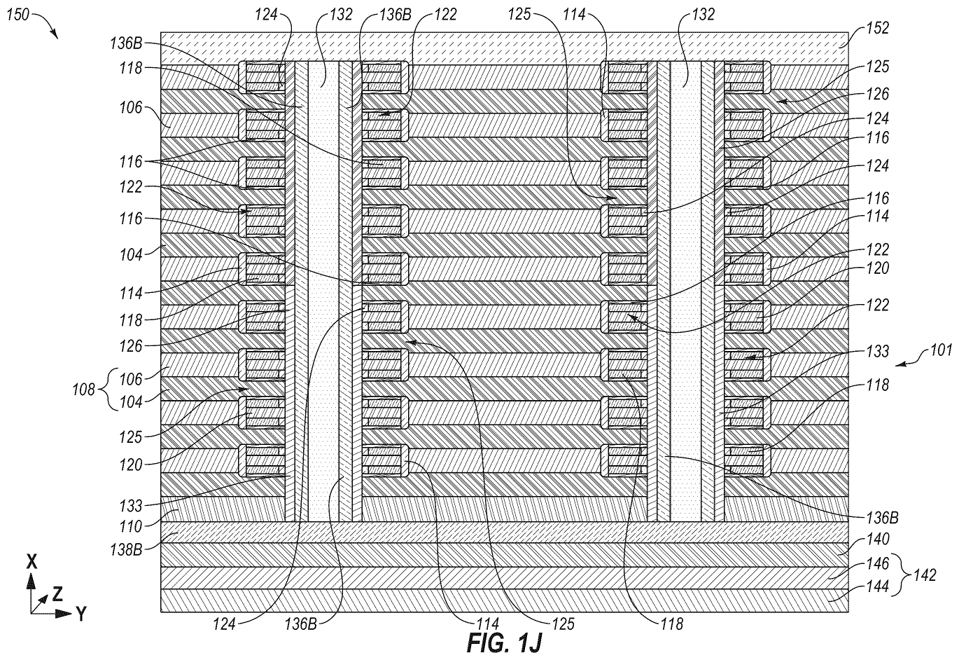

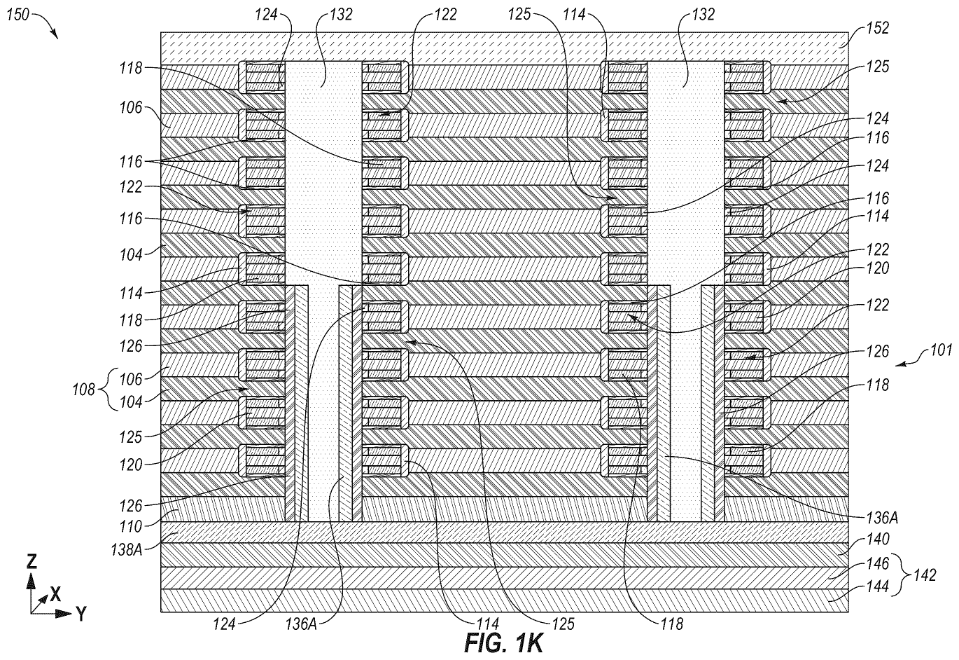

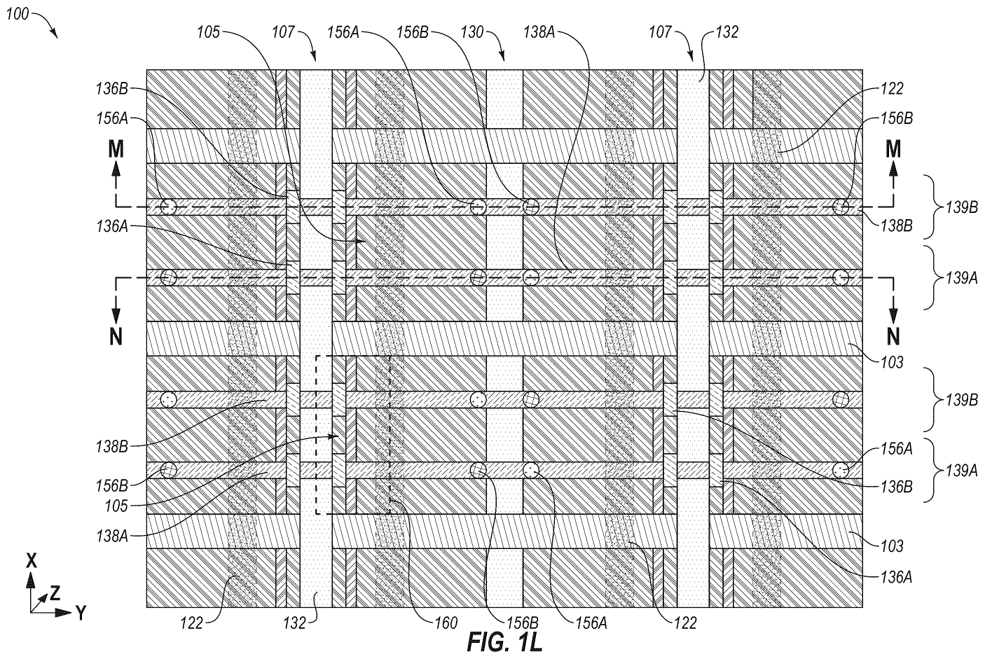

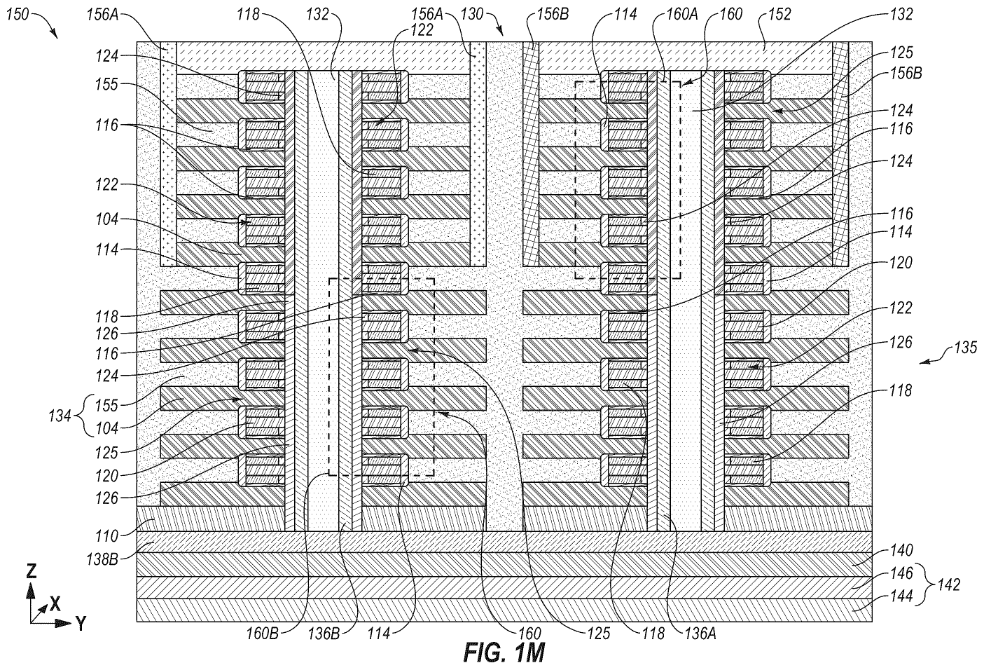

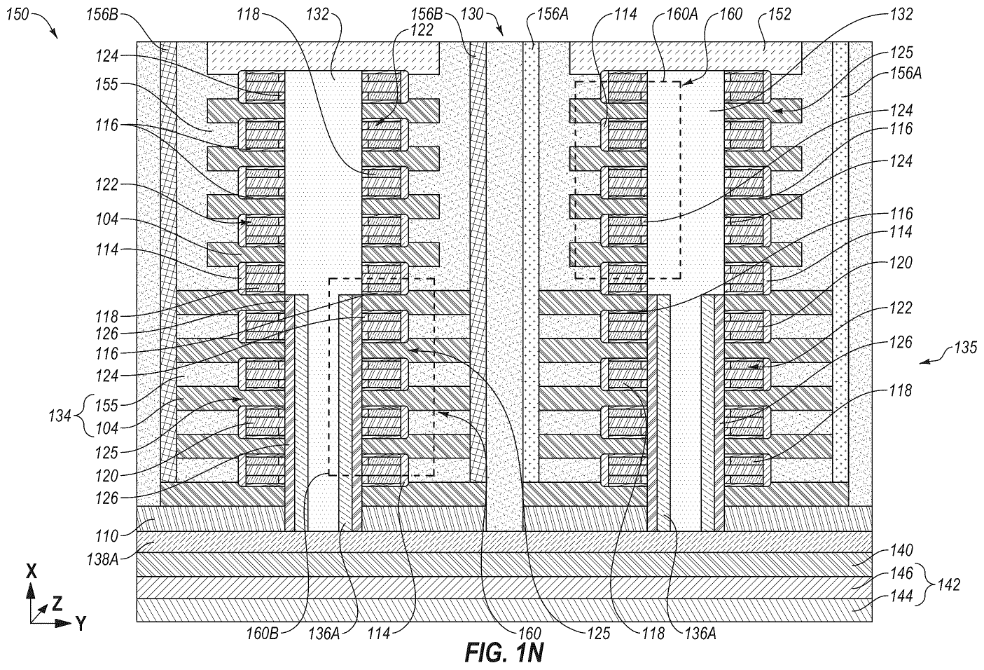

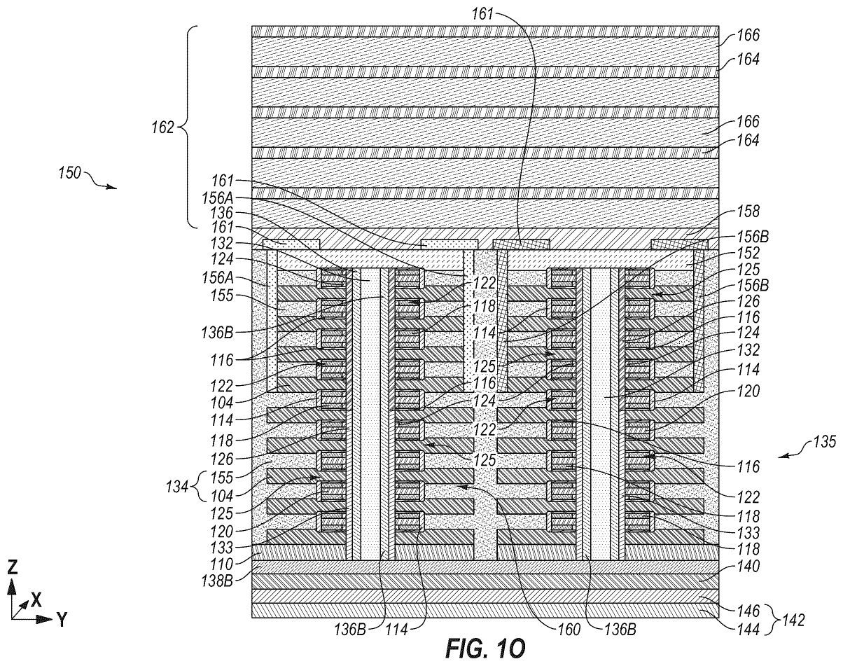

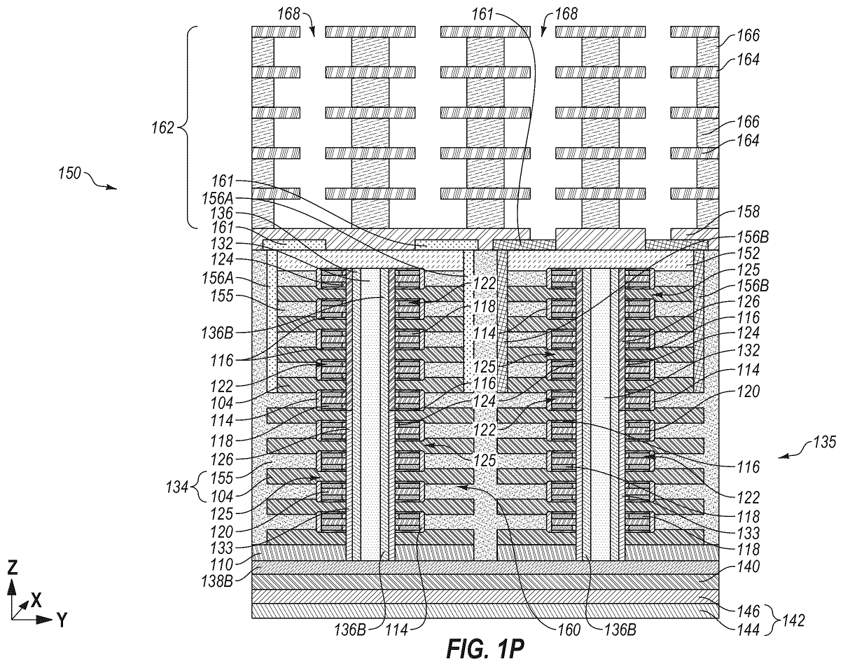

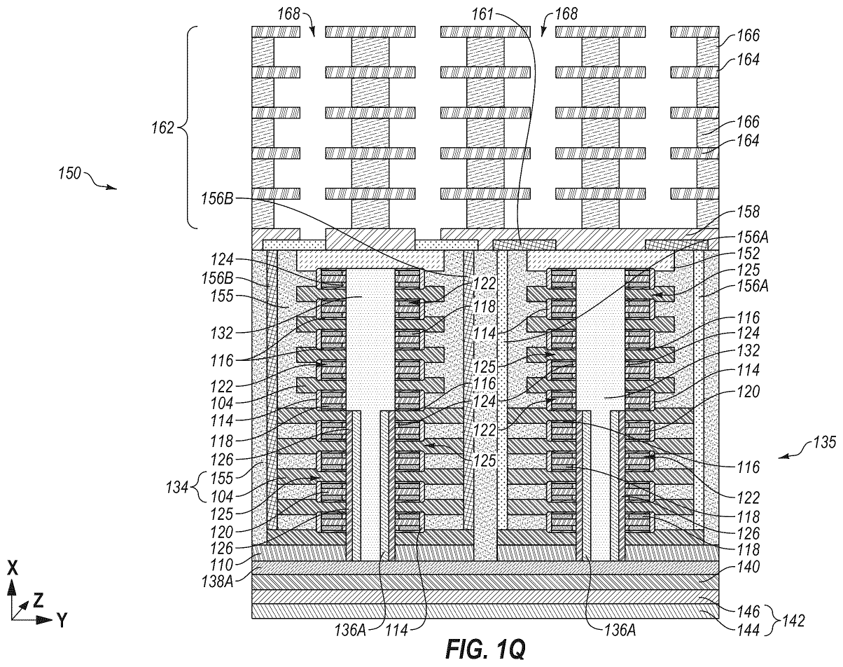

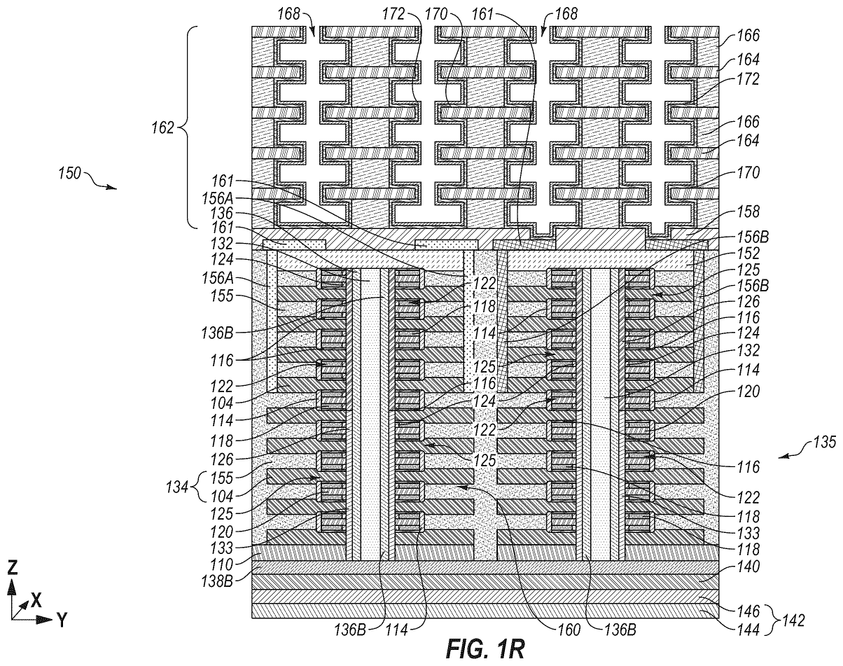

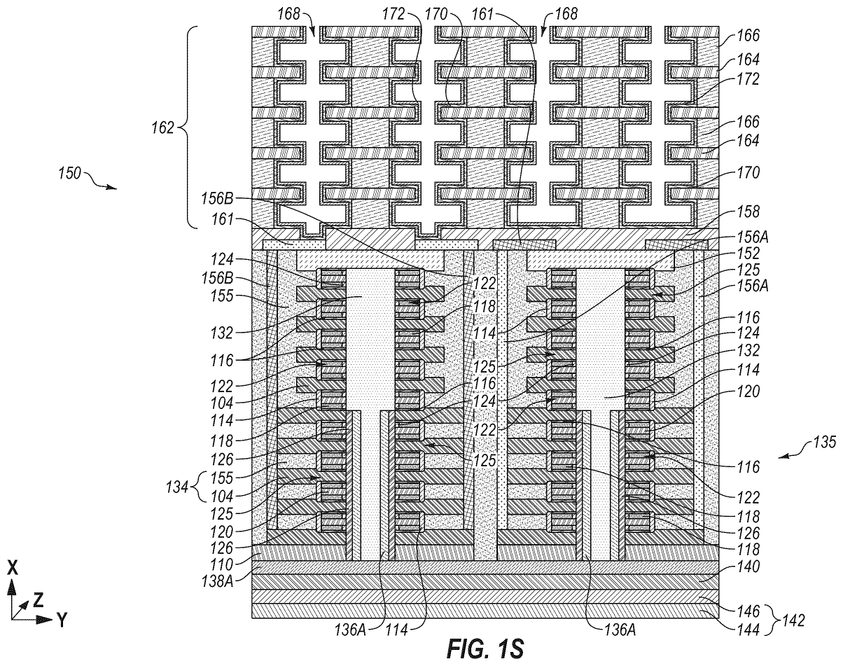

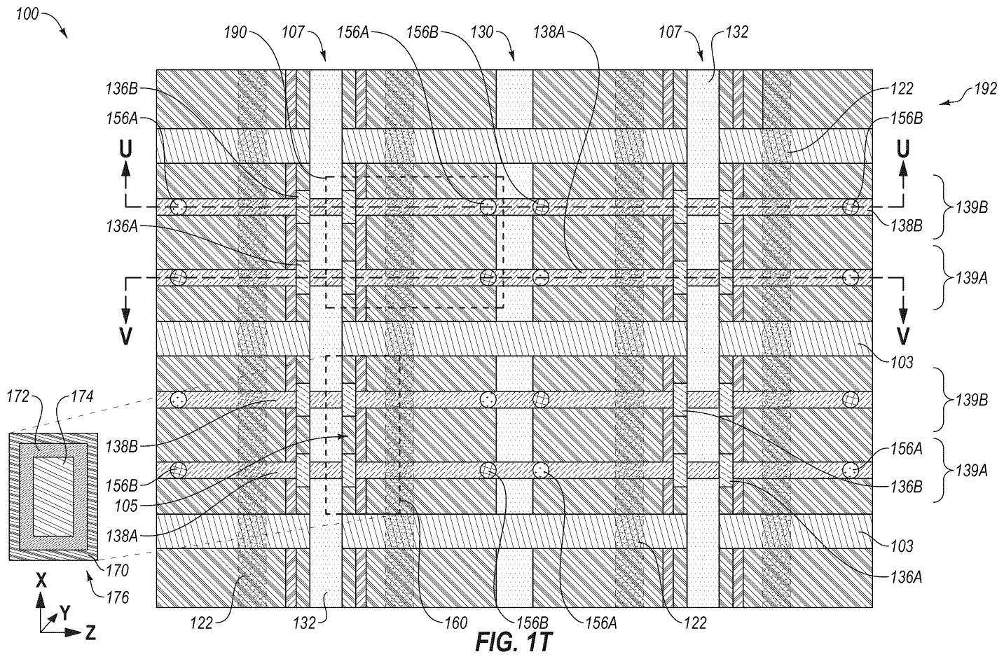

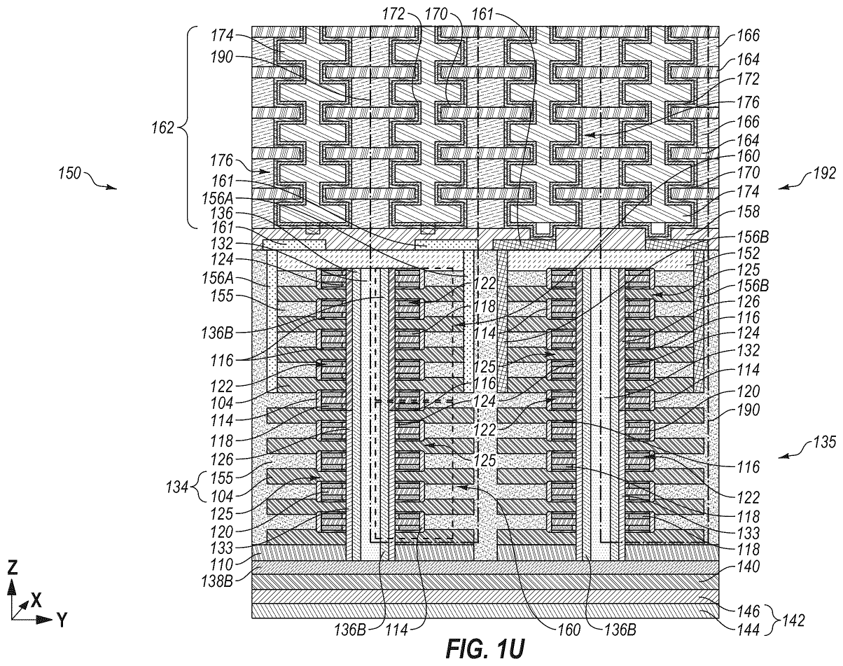

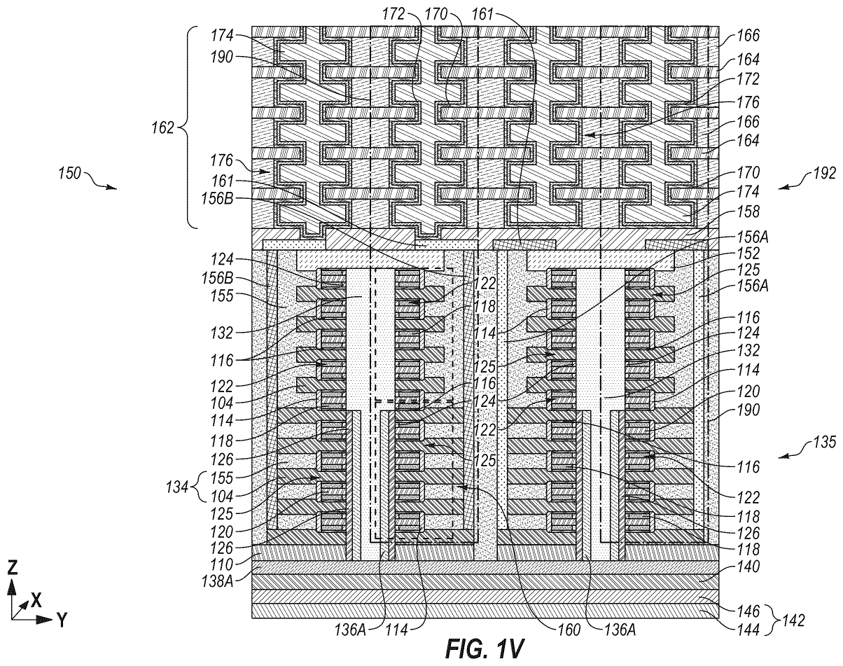

FIG. 1A through FIG. 1V are various views (described in further detail below) illustrating a microelectronic device structure at different processing stages of a method of forming a microelectronic device (e.g., a memory device, such as a DRAM memory device), in accordance with embodiments of the disclosure. With the description provided below, it will be readily apparent to one of ordinary skill in the art that the methods described herein may be used for forming various devices. In other words, the methods of the disclosure may be used whenever it is desired to form a microelectronic device.

FIG. 1A is a simplified, partial top-down view of a microelectronic device structure 100, in accordance with embodiments of the disclosure. FIG. 1B is a simplified, partial cross-sectional view of the microelectronic device structure 100 taken through section line B-B of FIG. 1A. With reference to FIG. 1A and FIG. 1B, the microelectronic device structure 100 includes active regions 105 (FIG. 1A) separated from one another by first trenches 107 extending in a first horizontal direction (e.g., in the X-direction) and a first insulative material 103 extending in a second horizontal direction (e.g., in the Y-direction). The first trenches 107 may be separated by the portions of the first insulative material 103. In the view of FIG. 1A, it will be understood that the Z-axis is in and out of the view of the page.

Referring to FIG. 1B, the microelectronic device structure 100 includes a stack structure 101 comprising a vertically alternating (e.g., in the Z-direction) sequence of a first material 104 and a second material 106 arranged in tiers 108 and vertically overlying (e.g., in the Z-direction) a base structure 102.

The stack structure 101 may be formed to include any desired number of the tiers 108. By way of non-limiting example, the stack structure 101 may be formed to include eight (8) of the tiers 108. In other embodiments, the stack structure 101 may be formed to include less than eight (8) of the tiers 108, such as less than or equal to four (4) of the tiers 108. In some embodiments, the stack structure 101 is formed to include two (2) of the tiers 108. As described in further detail herein, a quantity of the tiers 108 may correspond to an equivalent channel length of transistors structures (e.g., transistor structures 160 (FIG. 1U, FIG. 1V)) of memory cells (e.g., memory cells 190 (FIG. 1U. FIG. 1V)).

The base structure 102 may include a conventional silicon substrate (e.g., a conventional silicon wafer), or another bulk substrate comprising a semiconductive material. As used herein, the term “bulk substrate” means and includes not only silicon substrates, but also silicon-on-insulator (SOI) substrates, such as silicon-on-sapphire (SOS) substrates and silicon-on-glass (SOG) substrates, epitaxial layers of silicon on a base semiconductive foundation, and other substrates formed of and including one or more semiconductive materials (e.g., one or more of a silicon material, such monocrystalline silicon or polycrystalline silicon; silicon-germanium; germanium; gallium arsenide; a gallium nitride; and indium phosphide). In some embodiments, the base structure 102 comprises a silicon wafer.

The second material 106 of each of the tiers 108 of the stack structure 101 may be formed of and include at least one material that may be selectively removed relative to the first material 104. The second material 106 may be selectively etchable relative to the first material 104 during common (e.g., collective, mutual) exposure to a first etchant; and the first material 104 may be selectively etchable to the second material 106 during common exposure to a second, different etchant. As used herein, a material is “selectively etchable” relative to another material if the material exhibits an etch rate that is at least about five times (5×) greater than the etch rate of another material, such as about ten times (10×) greater, about twenty times (20×) greater, or about forty times (40×) greater.

The first material 104 may be formed of and include, for example, a semiconductive material (e.g., silicon) or an oxide material (e.g., silicon dioxide). In some embodiments, the first material 104 comprises silicon, such as epitaxially grown silicon. In some embodiments, the first material 104 comprises monocrystalline silicon.

The second material 106 may have a different material composition than the first material 104 and may have etch selectivity with respect to the first material 104. The second material 106 may be formed of and include one or more of silicon germanium, polysilicon, a nitride material (e.g., silicon nitride (Si₃N₄)), or an oxynitride material (e.g., silicon oxynitride). In some embodiments, such as where the first material 104 comprises silicon, the second material 106 comprises silicon germanium, such as epitaxially grown silicon germanium. In other embodiments, such as where the first material 104 comprises silicon, the second material 106 comprises polysilicon. In yet other embodiments, such as where the first material 104 comprises silicon dioxide, the second material 106 comprises silicon nitride or silicon oxynitride.

The first insulative material 103 may be formed of and include one or more of at least one insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), and at least one dielectric carboxynitride material (e.g., a silicon carboxynitride (SiOₓC_{z}N_{y})). In some embodiments, the first insulative material 103 is formed of and includes a dielectric oxide material, such as SiOₓ (e.g., SiO₂).

A second insulative material 110 may vertically overlie (e.g., in the Z-direction) the stack structure 101. The second insulative material 110 may be formed of and include insulative material, such as one or more of the materials described above with reference to the first insulative material 103. In some embodiments, the second insulative material 110 comprises silicon dioxide.

With reference to FIG. 1B, the first trenches 107 may vertically extend (e.g., in the Z-direction) through the second insulative material 110, the stack structure 101, and at least partially through the base structure 102. A horizontally extending (e.g., in the X-direction, in the Y-direction) surface of the base structure 102 may be exposed through the first trenches 107. In addition, horizontal sides of the first material 104 and the second material 106 may be exposed through the first trenches 107.

FIG. 1C is a simplified partial, cross-sectional view of the microelectronic device structure 100 at a processing stage subsequent to that illustrated in FIG. 1A and FIG. 1B. With reference to FIG. 1C, portions of the second material 106 exposed through the sidewalls defining the first trenches 107 may be selectively removed relative to the first material 104. Selective removal of the second material 106 relative to the first material 104 may form recesses 112 defined by exposed portions of the second material 106 recessed (e.g., in the Y-direction) relative to the first trenches 107 and exposed portions of the first material 104 (e.g., extending in the Y-direction).

In some embodiments, portions of the levels of the first material 104 are removed during removal of the second material 106 through the first trenches 107. In some embodiments, horizontally extending (e.g., in the Y-direction) portions of the levels of the first material 104 that are vertically separated (e.g., in the Z-direction) from one another by the recesses 112 may be partially removed such that portions of the first material 104 proximate the first trenches 107 and exposed by the recesses 112 have a smaller thickness (e.g., in the Z-direction) than other portions of the first material 104 distal from the first trenches 107.

In some embodiments, the portions of the second material 106 are selectively removed relative to the first material 104 by exposing the second material 106 to one or both of a dry etch process and a wet etch process. By way of non-limiting example, the second material 106 may be removed selective to the first material 104 by exposing the second material 106 to a dry etch including one or both of hydrogen fluoride (HF) and methanol (CH₃OH); followed by a plasma treatment with one or more of carbon tetrafluoride (CF₄), fluorine (F₂), ammonia (NH₃), argon, and chlorine trifluoride (ClF₃).

After forming the recesses 112, a third insulative material 114 may be formed within the first trenches 107 and within the recesses 112 on exposed surfaces of the first material 104, the second material 106, and the base structure 102.

The third insulative material 114 may be formed by, for example, depositing a liner material comprising the third insulative material 114 and removing portions of the liner material from surfaces of the base structure 102 and from horizontally extending (e.g., in the X-direction, in the Y-direction) surfaces of the first material 104 proximate the first trenches 107. The third insulative material 114 may remain on surfaces of the second material 106 and vertically extend (e.g., in the Z-direction) between vertically neighboring (e.g., in the Z-direction) levels of the first material 104 at locations distal from the first trenches 107.

The third insulative material 114 may be formed of and include insulative material having an etch selectivity with respect to the first material 104, the second material 106, and a dielectric material 116. In some embodiments, the third insulative material 114 comprises a nitride material (e.g., silicon nitride (Si₃N₄)) or an oxynitride material (e.g., silicon oxynitride). In some embodiments, the third insulative material 114 comprises silicon nitride.

After forming third insulative material 114, a dielectric material 116 may be formed on horizontally extending (e.g., in the X-direction, in the Y-direction) surfaces of the first material 104. In some embodiments, the dielectric material 116 is grown on exposed surfaces of the first material 104. By way of non-limiting example, the dielectric material 116 may be formed by exposing surfaces of the first material 104 to oxygen at an elevated temperature (e.g., at a temperature within a range of from about 900° C. to about 1,200° C.).

In other embodiments, the dielectric material 116 is formed by depositing the dielectric material 116 on surfaces defining the recesses 112 (e.g., horizontally extending (e.g., in the X-direction, in the Y-direction) surfaces of the first material 104) and vertically extending (e.g., in the Z-direction) surfaces of the third insulative material 114. The portions of the dielectric material 116 on vertically extending surfaces of the third insulative material 114 and on surfaces within the first trenches 107 and outside of the first trenches 107 may be removed.

The dielectric material 116 may also be referred to herein as a “gate dielectric material.” As described in further detail herein, the dielectric material 116 is vertically interposed between (e.g., in the Z-direction) the first material 104 and a conductive material (e.g., conductive material 118 (FIG. 1D)).

The dielectric material 116 may be formed of and include insulative material. By way of non-limiting example, the dielectric material 116 may comprise one or more of phosphosilicate glass, borosilicate glass, borophosphosilicate glass (BPSG), fluorosilicate glass, silicon dioxide, titanium dioxide, zirconium dioxide, hafnium dioxide, tantalum oxide, magnesium oxide, aluminum oxide, niobium oxide, molybdenum oxide, strontium oxide, barium oxide, yttrium oxide, a nitride material, (e.g., silicon nitride (Si₃N₄)), an oxynitride (e.g., silicon oxynitride), another gate dielectric material, a dielectric carbon nitride material (e.g., silicon carbon nitride (SiCN)), or a dielectric carboxynitride material (e.g., silicon carboxynitride (SiOCN)).

FIG. 1D is a simplified partial, cross-sectional view of the microelectronic device structure 100 at a processing stage subsequent to that illustrated in FIG. 1C. With reference to FIG. 1D, after forming the dielectric material 116, a conductive material 118 may be formed within the first trenches 107 and the recesses 112 (FIG. 1C) on surfaces of the dielectric material 116 within the recesses 112 and on vertically extending (e.g., in the Z-direction) surfaces of the first material 104 defining sidewalls of the first trenches 107.

After forming the conductive material 118, a fourth insulative material 120 may be formed on surfaces of the conductive material 118 within the recesses 112 (FIG. 1C) and within the first trenches 107. In some embodiments, the fourth insulative material 120 substantially fills remaining portions of the recesses 112.

The conductive material 118 may be formed of and include conductive material, such as, for example, one or more of a metal (e.g., tungsten, titanium, nickel, platinum, rhodium, ruthenium, aluminum, copper, molybdenum, iridium, silver, gold), a metal alloy, a metal-containing material (e.g., metal nitrides, metal silicides, metal carbides, metal oxides), a material including at least one of titanium nitride (TiN), tantalum nitride (TaN), tungsten nitride (WN), titanium aluminum nitride (TiAIN), iridium oxide (IrOₓ), ruthenium oxide (RuOₓ), alloys thereof, a conductively doped semiconductor material (e.g., conductively doped silicon, conductively doped germanium, conductively doped silicon germanium, etc.), polysilicon, or other materials exhibiting electrical conductivity.

The fourth insulative material 120 may be formed of and include insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), and at least one dielectric carboxynitride material (e.g., a silicon carboxynitride (SiOₓC_{z}N_{y})). In some embodiments, the fourth insulative material 120 is formed of and includes a dielectric oxide material, such as SiOₓ (e.g., SiO₂).

After forming the conductive material 118 and the fourth insulative material 120, portions of the fourth insulative material 120 may be removed from within the first trenches 107 and from vertically uppermost (e.g., in the Z-direction) surfaces of the microelectronic device structure 100. The fourth insulative material 120 may remain at portions corresponding to the locations of the recesses 112 (FIG. 1C) vertically between (e.g., in the Z-direction) levels of the first material 104.

After removing the portions of the fourth insulative material 120, portions of the conductive material 118 may be removed from within the first trenches 107 and from vertically uppermost (e.g., in the Z-direction) surfaces of the microelectronic device structure 100. Exposed portions of the conductive material 118 defining the sidewalls of the first trenches 107 may be recessed (e.g., in the Y-direction) relative to the surfaces of the fourth insulative material 120. In some embodiments, the conductive material 118 is selectively removed (e.g., in the Y-direction) relative to the fourth insulative material 120 and the first material 104 by exposing the conductive material 118 to a dry etchant comprising, for example, sulfur hexafluoride (SF₆) and nitrogen (N₂), nitrogen trifluoride (NF₃), hydrogen fluoride (HF), fluorine (F₂), and methyl fluoride (CH₃F). However, the disclosure is not so limited and the conductive material 118 may be selectively removed relative to the fourth insulative material 120 and the first material 104.

After removing the portions of the conductive material 118, remaining portions of the conductive material 118 may form conductive structures 122. The conductive structures 122 may vertically overlie (e.g., in the Z-direction) and vertically underlie (e.g., in the Z-direction) portions of each of the first materials 104. In some embodiments, vertically neighboring (e.g., in the Z-direction) conductive structures 122 between vertically neighboring (e.g., in the Z-direction) levels of the first material 104 are spaced from each other by the fourth insulative material 120. The dielectric material 116 may vertically intervene (e.g., in the Z-direction) between the conductive structures 122 and the first material 104.

The conductive structures 122 may horizontally extend (e.g., in the X-direction) as lines and may extend through an array region of the microelectronic device structure 100. As described in further detail herein, the conductive structures 122 may individually be referred to herein as “first conductive lines,” “access lines,” or “word lines.”

After recessing portions of the conductive material 118 and forming the conductive structures 122, a fifth insulative material 124 may be formed between horizontal edges (e.g., in the Y-direction) of the conductive structures 122 and the first trenches 107. After forming the fifth insulative material 124, portions of the fifth insulative material 124 within the first trenches 107 may be removed.

The fifth insulative material 124 may be formed of and include one or more of the materials described above with reference to the third insulative material 114. In some embodiments, the fifth insulative material 124 comprises substantially the same material composition as the third insulative material 114. In some embodiments, the fifth insulative material 124 comprises silicon nitride.

Channel regions 125 may be formed within the levels of the first material 104 between vertically neighboring (e.g., in the Z-direction) levels of the second material 106. The channel regions 125 may individually be vertically between (e.g., in the Z-direction) vertically neighboring (e.g., in the Z-direction) conductive structures 122. The conductive structures 122 are separated from the channel regions 125 by the dielectric material 116. As described in further detail herein, different vertical levels (e.g., in the Z-direction) of the channel regions 125 may form vertically spaced (e.g., in the Z-direction) transistor structures (e.g., transistor structure 160 (FIG. 1U, FIG. 1V)) to form vertically stacked (e.g., in the Z-direction) transistor structures, each transistor structure comprising multiple (e.g., more than one) levels of channel regions 125.

In some embodiments, the conductive structures 122 are vertically stacked (e.g., in the Z-direction) with respect to one another and vertically spaced (e.g., in the Z-direction) from one another by the channel regions 125, the dielectric materials 116, and the fourth insulative material 120.

FIG. 1E is a simplified partial, top-down view of the microelectronic device structure 100 at a processing stage subsequent to that illustrated in FIG. 1D. FIG. 1F is a simplified partial, cross-sectional view of the microelectronic device structure 100 at a processing stage subsequent to that illustrated in FIG. 1E. After forming the fifth insulative material 124, a conductive material 126 may be formed within the first trenches 107 and between horizontally neighboring (e.g., in the X-direction) portions of the first insulative material 103. Accordingly, different portions of the conductive material 126 may be electrically isolated from one another by the first insulative material 103. After forming the conductive material 126, horizontally extending portions (e.g., in the X-direction, in the Y-direction) of the conductive material 126 may be removed, such as by exposing the conductive material 126 to a dry etch process including one or more of trichlorofluoromethane (CFCL₃), chlorotrifluoromethane (CF₃CL), bromotrifluoromethane (CF₃Br), CF₄, hexafluoroethane (C₂F₆), SF₆, and a mixture of hydrogen bromide (HBr) and oxygen (O₂). Removing the horizontally extending portions of the conductive material 126 may electrically isolate different portions of the conductive material 126 separated from one another by the first trenches 107.

The conductive material 126 may contact the sidewalls of the levels of the first material 104 and the sides of the fifth insulative material 124 and the fourth insulative material 120. In use and operation, the conductive material 126 may be in electrical communication with the first material 104. In some such embodiments, electrical current flows between the conductive material 126 and the first material 104 (e.g., from the conductive material 126 to the first material 104, from the first material 104 to the conductive material 126).

In some embodiments, after removing a vertically lowermost (e.g., in the Z-direction) portion of the conductive material 126, portions of the base structure 102 are removed through the first trenches 107.

The conductive material 126 may be formed of and include conductive material, such as one or more of the materials described above with reference to the conductive material 118. In some embodiments, the conductive material comprises conductively doped polysilicon, such as N+ doped polysilicon.

FIG. 1G is a simplified, partial top-down view of the microelectronic device structure 100 at a processing stage subsequent to that illustrated in FIG. 1E and FIG. 1F. FIG. 1H is a simplified, partial cross-sectional view of the microelectronic device structure 100 taken through section line H-H of FIG. 1G. FIG. 1I is a simplified, partial cross-sectional view of the microelectronic device structure 100 taken through section line I-I of FIG. 1H. In FIG. 1G, the conductive structures 122 are illustrated in broken lines to indicate that they are located in a different vertical plane (e.g., in the Z-direction) than other portions of the microelectronic device structure 100, such as vertically below (e.g., in the Z-direction) a vertically uppermost (e.g., in the Z-direction) upper surface of the microelectronic device structure 100. For clarity and case of understanding the description, FIG. 1G illustrates portions of the microelectronic device structure 100 located vertically underneath (e.g., in the Z-direction) an uppermost surface of the microelectronic device structure 100. For example, FIG. 1G illustrates the relative location of different structures and components of the microelectronic device structure 100 in the XY plane. By way of non-limiting example, although the conductive structures 122 and the conductive material 126 may not be at the vertically uppermost (e.g., in the Z-direction) surface of the microelectronic device structure 100, FIG. 1G illustrates the conductive structures 122 and the conductive material 126 to show the relative location of the conductive structures 122 and the conductive material 126 with respect to other components and structures of the microelectronic device structure 100.

With collective reference to FIG. 1G through FIG. 1I, portions of conductive material 126 horizontally extending (e.g., in the Y-direction) may be removed to electrically isolate horizontally neighboring (e.g., in the Y-direction) portions of the conductive material 126. In addition, and with reference to FIG. 1H, in some embodiments, conductive contact structures 136 may be formed to individually vertically extend (e.g., in the Z-direction) at least partially through the first trenches 107 (FIG. 1F, FIG. 1G) and each individually configured to be in electrical communication with some of (e.g., one half of) the channel regions 125 directly horizontally neighboring (e.g., in the Y-direction) the conductive contact structure 136. In some embodiments, about one half of the conductive contact structures 136 are configured to be in electrical communication with the vertically uppermost (e.g., in the Z-direction) one half of the channel regions 125 (e.g., the vertically uppermost four levels of the channel regions 125) and may be referred to herein as first conductive contact structures 136A; and the other one half of the first conductive contact structures 136A are configured to be in electrical communication with the vertically lowermost (e.g., in the Z-direction) one half of the channel regions 125 (e.g., the vertically lowermost four levels of the channel regions 125) and may be referred to herein as second conductive contact structures 136B. The first conductive contact structures 136A and the second conductive contact structures 136B are collectively referred to herein as conductive contact structures 136.

In some embodiments, first conductive contact structures 136A horizontally neighboring one another in a first horizontal direction (e.g., in the X-direction) may be horizontally aligned with one another in a second horizontal direction (e.g., in the Y-direction); and first conductive contact structures 136A horizontally neighboring one another in the second horizontal direction may be horizontally offset from one another in the first horizontal direction. Similarly, second conductive contact structures 136B horizontally neighboring one another in the first horizontal direction (e.g., in the X-direction) may be horizontally aligned with one another in the second horizontal direction (e.g., in the Y-direction); and second conductive contact structures 136B horizontally neighboring one another in the second horizontal direction may be horizontally offset from one another in the first horizontal direction. In addition, in some embodiments, a second conductive contact structure 136B horizontally neighboring a first conductive contact structure 136A in the first horizontal direction (e.g., in the X-direction) may be horizontally aligned with the first conductive contact structure 136A in the second horizontal direction (e.g., in the Y-direction).

In some embodiments, the first conductive contact structures 136A are horizontally aligned (e.g., in the X-direction) with one another and may be located in first regions 139A (FIG. 1G) of the microelectronic device structure 100; and the second conductive contact structures 136B are horizontally aligned (e.g., in the X-direction) with one another and located in second regions 139B (FIG. 1G) of the microelectronic device structure 100. The first regions 139A may horizontally alternate (e.g., in the X-direction) with the second regions 139B, as described above with reference to the first conductive lines 138A and the second conductive lines 138B.

With collective reference FIG. 1G and FIG. 1H, a mask material may be formed over the first regions 139A of the microelectronic device structure 100; portions of the second conductive contact structures 136B are formed in the first trenches 107 in the second regions 139B and on surfaces of the conductive material 126; and a sixth insulative material 132 is formed in remaining portions of the first trenches 107. After forming the portions of the second conductive contact structures 136B and the sixth insulative material 132, the conductive material 126, the portions of the first conductive contact structures 136A, and the sixth insulative material 132 may be removed from vertically uppermost (e.g., in the Z-direction) portions of the first trenches 107, such as from the vertically uppermost one half of the levels of the first material 104 and the second material 106.

With continued reference to FIG. 1H, a liner material 133 may be formed on surfaces of the vertically uppermost (e.g., in the Z-direction) levels of the first material 104 and the second material 106, such as the vertically uppermost one half of the levels within the first trenches 107 in the second regions 139B. After forming the liner material 133, additional portions of the second conductive contact structures 136B may be formed within the first trenches 107, on surfaces of the liner material 133 and in electrical communication with the previously formed portions of the second conductive contact structures 136B to form the second conductive contact structures 136B vertically extending (e.g., in the Z-direction) through substantially the entire stack structure 101. The liner material 133 may electrically isolate the vertically uppermost (e.g., in the Z-direction) (e.g., the vertically uppermost one half) levels of the channel regions 125 from the second conductive contact structures 136B.

With reference to FIG. 1I, after forming the second conductive contact structures 136B (FIG. 1G, FIG. 1H) in the second regions 139B (FIG. 1G), a mask material may be formed over the second regions 139B and first conductive contact structures 136A may be formed in the first regions 139A. By way of non-limiting example, the conductive material 126 may be removed from the vertically lower (e.g., in the Z-direction) portions of the first trenches 107 and the sixth insulative material 132 may be formed in the lower portions of the first trenches 107 within the first regions 139A. After forming the sixth insulative material 132 in the vertically lower portions of the first trenches 107, additional portions of the conductive material 126 may be formed on surfaces of the levels of the first material 104 in the vertically upper (e.g., in the Z-direction) portions of the first trenches 107 within the first regions 139A; additional first conductive contact structures 136A may be formed on surface of and in contact with the conductive material 126, and additional portions of the sixth insulative material 132 may be formed in remaining portions of the first trenches 107 within the first regions 139A.

Accordingly, with reference to FIG. 1H and FIG. 1I, the first conductive contact structures 136A (FIG. 1G, FIG. 1H) may be configured to be in electrical communication with the vertically lowermost (e.g., in the Z-direction) levels of the channel regions 125 and not in electrical communication with the vertically uppermost (e.g., in the Z-direction) levels of the channel regions 125 (e.g., the first conductive contact structures 136A may be electrically isolated from the vertically uppermost levels of the channel regions 125 by the liner material 133); and the second conductive contact structures 136B (FIG. 1G, FIG. 1I) may be configured to be in electrical communication with the vertically uppermost (e.g., in the Z-direction) levels of the channel regions 125 and not in electrical communication with the vertically lowermost (e.g., in the Z-direction) levels of the channel regions.

After forming the first conductive contact structures 136A within the upper portions of the first trenches 107 and configured to be in electrical communication with the vertically upper (e.g., in the Z-direction) one half of the levels of the channel regions 125, and forming the second conductive contact structures 136B within the lower portions and the upper portions of the first trenches 107 and configured to be in electrical communication with the vertically lower (e.g., in the Z-direction) one half of the levels of the channel regions 125, conductive lines 138 may be formed over the microelectronic device structure 100 and in electrical communication with the first conductive contact structures 136A and the second conductive contact structures 136B. For example, first conductive lines 138A may be formed in electrical communication with the first conductive contact structures 136A in the first regions 139A, and second conductive lines 138B may be formed in electrical communication with the second conductive contact structures 136B in the second regions 139B. In other words, the first conductive contact structures 136A may electrically connect the first conductive lines 138A in contact with the first conductive contact structures 136A to the first materials 104 of the levels of the first materials 104 by means of the conductive material 126; and the second conductive contact structures 136B may electrically connect the second conductive lines 138B in contact with the second conductive contact structures 136B to the first materials 104 of the levels of the first materials 104 by means of the conductive material 126. In use and operation, application of a voltage to, for example, the conductive structures 122 may induce an electric current in the first material 104 vertically between (e.g., in the Z-direction) the conductive structures 122 and electrically connect the conductive line 138 to a storage device (e.g., storage device 176 (FIG. 1U, FIG. 1V)) in electrical communication with the first material 104.

Accordingly, in some embodiments, one half of the conductive lines 138 (e.g., the first conductive lines 138A) are configured to be in electrical communication with the vertically uppermost (e.g., in the Z-direction) half of the vertical levels of the channel regions 125 (e.g., through the corresponding first conductive contact structures 136A); and the other one half of the conductive lines 138 (e.g., the second conductive lines 138B) are configured to be in electrical communication with the vertically lowermost (e.g., in the Z-direction) one half of the vertical levels of the channel regions 125 (e.g., through the corresponding other one half of the second conductive contact structures 136B). The first conductive lines 138A and the second conductive lines 138B may collectively be referred to herein as conductive lines 138.

The first conductive lines 138A may horizontally alternate (e.g., in the X-direction) with the second conductive lines 138B, such that each of the first conductive lines 138A and the second conductive lines 138B are horizontally neighbored (e.g., in the X-direction) by the other of the first conductive lines 138A and the second conductive lines 138B. Conductive lines 138 that directly horizontally neighbor one another (e.g., in the X-direction) may be in electrical communication with conductive contact structures 136 that are, in turn, in electrical communication with different levels of the channel regions 125 (e.g., the first conductive line 138A is in electrical communication with the vertically uppermost (e.g., in the Z-direction) one half of the channel regions 125 by means of the first conductive contact structures 136A and the second conductive line 138B directly horizontally neighboring (e.g., in the X-direction) the first conductive line 138A is in electrical communication with the vertically lowermost (e.g., in the Z-direction) one half of the channel regions 125 by means of the second conductive contact structures 136B).

In some embodiments, the first conductive lines 138A are horizontally aligned (e.g., in the X-direction) with corresponding first conductive contact structures 136A; and the second conductive lines 138B are horizontally aligned (e.g., in the X-direction) with corresponding second conductive contact structures 136B. In other words, the conductive lines 138 may individually be in contact with conductive contact structures 136 that are horizontally aligned with one another in a first direction (e.g., in the X-direction) and horizontally spaced from one another in a second direction (e.g., in the Y-direction). In some such embodiments, an individual conductive line 138 may be in contact with first conductive contact structures 136A that are located within horizontal boundaries (e.g., in the X-direction) of one another.

The first conductive lines 138A and the first conductive contact structures 136A may be located in first regions 139A (FIG. 1G) of the microelectronic device structure 100; and the second conductive lines 138B and the second conductive contact structures 136B may be located in second regions 139B (FIG. 1G) of the microelectronic device structure 100. The first regions 139A may horizontally alternate (e.g., in the X-direction) with the second regions 139B, as described above with reference to the first conductive lines 138A and the second conductive lines 138B.

The conductive lines 138 may horizontally extend (e.g., in the Y-direction) substantially perpendicularly to the conductive structures 122. The conductive lines 138 may be employed as digit lines (e.g., data lines, bit lines). Since the conductive contact structures 136 are in contact with the conductive lines 138 and configured to be electrically connected to the conductive lines 138, the conductive contact structures 136 may be employed as digit line contacts (also referred to herein as “digit line contact structures”). The conductive lines 138 may vertically overlie (e.g., in the Z-direction) the conductive structures 122. With reference to FIG. 1G, while the conductive structures 122 are illustrated in the top-down view of FIG. 1G, it will be understood that the conductive structures 122 are vertically below (e.g., in the Z-direction) the conductive lines 138. The conductive structures 122 do not contact the conductive lines 138. The conductive structures 122 are illustrated in broken lines in FIG. 1G and the other top-down views herein to indicate that they are located below other portions of the microelectronic device structure 100 (e.g., such as the conductive lines 138). The relative vertical locations (e.g., in the Z-direction) of different components of the microelectronic device structure 100 are best illustrated in the cross-sectional views (e.g., such as FIG. 1H and FIG. 1I), while the relative horizontal positioning (e.g., in the X-direction, in the Y-direction) are best illustrated in the top-down views (e.g., such as FIG. 1G).

The conductive contact structures 136 and the conductive lines 138 may individually be formed of and include conductive material, such as one or more of the materials described above with reference to the conductive material 118. In some embodiments, the conductive contact structures 136 and the conductive lines 138 individually comprise tungsten.

The liner material 133 and the sixth insulative material 132 may individually be formed of and include insulative material, such as one or more of the materials described above with reference to the first insulative material 103. In some embodiments, the liner material 133 and the sixth insulative material 132 individually comprise silicon dioxide.

While the conductive material 126 has been described and illustrated as being formed as a liner material within the first trenches 107 (FIG. 1G), the disclosure is not so limited. In other embodiments, the conductive material 126 may be formed as contact structures, substantially similar to the conductive contact structures 136, the conductive material 126 in contact with the channel regions 125 and horizontally intervening (e.g., in the Y-direction) between the channel regions and the conductive contact structures 136. In other embodiments, the conductive material 126 may selectively be epitaxially grown on the first material 104 relative to the first insulative material 103 (FIG. 1A, FIG. 1G) such that portions of the conductive material 126 on horizontally opposing sides (e.g., in the Y-direction) of the first trenches 107 are electrically isolated from one another. In some embodiments, the conductive material 126 is doped with one or more dopants to increase an electrical conductivity of the conductive material 126. By way of non-limiting example, portions of the conductive material 126 within horizontal boundaries (e.g., in the X-direction) of the conductive contact structures 136 and horizontally intervening (e.g., in the Y-direction) between the conductive contact structures 136 and the channel regions 125 may be doped while other positions of the conductive material 126 may not be doped.

FIG. 1J and FIG. 1K are simplified, partial cross-sectional views of the microelectronic device structure 100 at a processing stage subsequent to that illustrated in FIG. 1G through FIG. 1I. The cross-sectional view of FIG. 1J is taken through the same plane as that illustrated in FIG. 1H and the cross-sectional view of FIG. 1K is taken through the same plane as that illustrated in FIG. 1I, but at a subsequent processing stage than that illustrated and described with reference to FIG. 1H and FIG. 1I, respectively.

With reference to FIG. 1J and FIG. 1K, after forming the conductive contact structures 136 and the conductive lines 138, a seventh insulative material 140 is formed over the conductive lines 138. The seventh insulative material 140 may be formed of and include one or more of the materials described above with reference to the first insulative material 103. In some embodiments, the seventh insulative material 140 comprises an oxide material, such as silicon dioxide.

After forming the seventh insulative material 140, the microelectronic device structure 100 may be vertically inverted (e.g., flipped upside down in the Z-direction) and attached (e.g., bonded) to a carrier wafer 142 comprising a second base structure 144 and an oxide material 146 overlying the second base structure 144 to form a microelectronic device structure assembly 150 comprising the microelectronic device structure 100 and the carrier wafer 142. The carrier wafer 142 may be configured to facilitate safe handling of the microelectronic device structure assembly 150 for further processing of the microelectronic device structure 100. The carrier wafer 142 may comprise a conventional carrier structure and is, therefore, not described in detail herein.

The oxide material 146 may be formed of and include an oxide insulative material, such as at least one dielectric oxide material (e.g., one or more of a silicon oxide (SiOₓ), phosphosilicate glass, borosilicate glass, borophosphosilicate glass, fluorosilicate glass, AlOₓ, HfOₓ, NbOₓ, TiOₓ, ZrOₓ, TaOₓ, and MgOₓ). In some embodiments, the oxide material 146 comprises silicon dioxide. In some embodiments, the oxide material 146 and the seventh insulative material 140 comprises substantially the same material composition (e.g., silicon dioxide).

The carrier wafer 142 may be attached to the microelectronic device structure 100 by contacting the seventh insulative material 140 of the microelectronic device structure 100 with the oxide material 146 of the carrier wafer 142. After the seventh insulative material 140 and the oxide material 146 are in contact, the microelectronic device structure 100 and the carrier wafer 142 may be exposed to annealing conditions to form bonds (e.g., oxide-to-oxide bonds) between the seventh insulative material 140 of the microelectronic device structure 100 and the oxide material 146 of the carrier wafer 142 to form the microelectronic device structure assembly 150. In some embodiments, the microelectronic device structure 100 and the carrier wafer 142 are exposed to a temperature greater than, for example, 800° C., to form the oxide-to-oxide bonds and attach the microelectronic device structure 100 to the carrier wafer 142.

After attaching the microelectronic device structure 100 to the carrier wafer 142, the base structure 102 (FIG. 1H, FIG. 1I) may be removed (e.g., thinned, etched), such as by exposing the base structure 102 to one or more etchants or by exposing the base structure 102 to a CMP process. In some embodiments, the base structure 102 is removed by exposing the base structure 102 to an etchant formulated and configured to stop on an insulative material (e.g., the sixth insulative material 132, the third insulative material 114, the dielectric material 116, the fifth insulative material 124).

After removing the base structure 102 (FIG. 1H, FIG. 1I), an eighth insulative material 152 is formed over the microelectronic device structure assembly 150 to cover exposed portions of the conductive contact structures 136 and the conductive material 126. The eighth insulative material 152 may be formed of and include insulative material, such as one or more of the materials described above with reference to the first insulative material 103. In some embodiments, the eighth insulative material 152 comprises silicon dioxide.

FIG. 1L through FIG. 1N are a simplified, partial top-down view (FIG. 1L) and simplified, partial cross-sectional views (FIG. 1L and FIG. 1M) of the microelectronic device structure assembly 150 at a processing stage subsequent to that illustrated in FIG. 1J and FIG. 1K. FIG. 1M is taken through section line M-M of FIG. 1L and FIG. 1N is taken through section line N-N of FIG. 1N.

With collective reference to FIG. 1L and FIG. 1N, after forming the eighth insulative material 152, second trenches 130 may be formed within the stack structure 101 between horizontally neighboring (e.g., in the Y-direction) first trenches 107. In some embodiments, the second trenches 130 (FIG. 1L) may horizontally extend in a horizontal direction (e.g., in the X-direction) substantially parallel to the first trenches 107 and substantially parallel to the conductive structures 122. The second trenches 130 may vertically extend (e.g., in the Z-direction) at least through a portion of the base structure 102.

After forming the second trenches 130, the second material 106 (FIG. 1J, FIG. 1K) may be selectively removed relative to the first material 104 through the second trenches 130, leaving voids vertically between (e.g., in the Z-direction) vertically neighboring (e.g., in the Z-direction) levels of the first material 104. Removal of the second material 106 through the second trenches 130 may expose vertically extending (e.g., in the Z-direction) sidewalls of the third insulative material 114. In some embodiments, the third insulative material 114 serves as an etch stop material and substantially reduces or prevents removal of the conductive material 118 of the conductive structures 122 during selective removal of the second materials 106.

The second material 106 may be selectively removed relative to the first material 104 by exposing the second material 106 to one or both of a vapor etching process and a dry etch process. By way of non-limiting example, the second material 106 may be removed selective to the first material 104 by exposing the second material 106 to a vapor etch comprising hydrogen fluoride and methanol (CH₃OH), followed by exposing the second material 106 to a plasma comprising one or more of CF₄, F₂, NH₃, argon (Ar), and chlorine trifluoride (ClF₃) (e.g., CF₄, a mixture of F₂ and NH₃, or a mixture of Ar and Fc).

After selectively removing the second material 106 (FIG. 1J, FIG. 1K) relative to the first material 104, the second trenches 130, and the regions vertically between (e.g., in the Z-direction) vertically neighboring (e.g., in the Z-direction) levels of the first material 104 may be filled with a ninth insulative material 155. The vertical levels of the ninth insulative material 155 may vertically alternate with the vertical levels of the first material 104 and may form a stack structure 135 comprising a vertically alternative sequence of tiers 134, each tier 134 comprising a vertical level of the first material 104 and a vertical level of the ninth insulative material 155.

Formation of the second trenches 130 may form electrically isolated transistor structures 160, each individually comprising multiple levels of the channel regions 125, each level of channel regions 125 located between vertically neighboring (e.g., in the Z-direction) levels of the ninth insulative material 155. Each isolated transistor structure 160 may include about one half of the levels of the channel regions 125 of the stack structure 135.

In some embodiments, the channel regions 125 of the transistor structures 160 individually comprise so-called “gate-all-around” (GAA) transistors. By way of non-limiting example, the conductive structures 122 may substantially surround the channel regions 125 of the transistor structures 160 and each channel region 125 may be surrounded by portions of the conductive structures 122 vertically above (e.g., in the Z-direction), vertically below (e.g., in the Z-direction), and horizontally around (e.g., in the X-direction, such as between the first insulative material 103 (FIG. 1A) and the channel region 125) the channel region 125.

Horizontal boundaries (e.g., in the X-direction, in the Y-direction) of each of the vertically neighboring (e.g., in the Z-direction) channel regions 125 of the transistor structures 160 may individually located within horizontal boundaries of the other channel regions 125 of the transistor structure 160.

In some embodiments, vertically upper (e.g., in the Z-direction) transistor structures 160 (one of which is illustrated in dashed box 160A) individually include vertically upper (e.g., in the Z-direction) levels of the channel regions 125, such as the vertically upper about one half of the levels of the channel regions 125; and vertically lower (e.g., in the Z-direction) transistor structures 160 (one of which is illustrated in dashed box 160B) individually include vertically lower (e.g., in the Z-direction) levels of the channel regions 125, such as the vertically lower about one half of the levels of the channel regions 125. In some embodiments, the microelectronic device structure assembly 150 includes two levels of transistor structures 160 vertically spaced from one another, each of the levels of transistor structures 160 individually comprising multiple vertical levels (e.g., vertically spaced levels) of channel regions 125. In some embodiments, each transistor structure 160 includes four (4) levels of the channel regions 125 directly vertically neighboring (e.g., in the Z-direction) one another. FIG. 1M and FIG. 1N each individually illustrate four upper transistor structures 160A and four (4) lower transistor structures 160B.

After replacing the second material 106 (FIG. 1J, FIG. 1K) with the levels of the ninth insulative material 155, additional conductive contact structures 156 (including third conductive contact structures 156A and fourth conductive contact structures 156B) may be formed vertically through the eighth insulative material 152 and through at least some levels of the ninth insulative material 155 and the first material 104. Each of the additional conductive contact structures 156 may individually be in electrical communication with one half of the vertical levels of the channel regions 125. For example, each of the additional conductive contact structures 156 is individually in contact with the channel regions 125 of one of the transistor structures 160 (e.g., one of the upper or lower transistor structures 160).

The additional conductive contact structures 156 include first additional conductive contact structures 156A (also referred to as “third conductive contact structures 156A”) each individually configured to be in electrical communication with, for example, an upper electrode of a storage device structure (e.g., storage device (FIG. 1U, FIG. 1V)); and second additional conductive contact structures 156B (also referred to as “fourth conductive contact structures 156B”) each individually configured to be in electrical communication with, for example, a lower electrode of the storage device (e.g., storage device (FIG. 1U, FIG. 1V)). The first additional conductive contact structures 156A and the second additional conductive contact structures 156B are collectively referred to herein as additional conductive contact structures 156. In some embodiments, along a conductive line 138, alternating pairs of the additional conductive contact structures 156 are in electrical communication with the conductive line 138. For example, a pair of the first additional conductive contact structures 156A may be in electrical communication with a conductive line 138 and horizontally spaced (e.g., in the Y-direction) from a pair of the second additional conductive contact structures 156 in electrical communication with the conductive line 138.

With continued reference to FIG. 1M and FIG. 1N, one half of the first additional conductive contact structures 156A are in contact with a first of the transistor structures 160 (e.g., the upper transistor structure 160A) and the other one half of the first additional conductive contact structures 156A are in contact with a second of the transistor structures 160 (e.g., the lower transistor structure 160B). In addition, one half of the second additional conductive contact structures 156B are in contact with a first of the transistor structures 160 (e.g., the upper transistor structure 160A) and the other one half of the second additional conductive contact structures 156B are in contact with a second of the transistor structures 160 (e.g., the lower transistor structure 160B).

In some embodiments, the additional conductive contact structures 156 are in contact with, for example, drain regions of the transistor structures 160 and the conductive contact structures 136 are in contact with source regions of the transistor structures 160, the multiple channel regions 125 of each of the transistor structures 160 horizontally between (e.g., in the Y-direction) the source regions and the drain regions.

Horizontally neighboring (e.g., in the Y-direction) additional conductive contact structures 156 that are in electrical communication with the same conductive line 138 may individually vertically extend (e.g., in the Z-direction) to a same location within the stack structure 135 and be in electrical communication with vertically aligned (e.g., in the Z-direction) transistor structures 160. By way of non-limiting example, the additional conductive contact structures 156 in electrical communication with the second conductive lines 138B may be in electrical communication with the vertically upper (e.g., in the Z-direction) transistor structures 160 (e.g., in the view of FIG. 1M and FIG. 1N, wherein the microelectronic device structure 100 is vertically flipped with respect to the view illustrated in FIG. 1H and FIG. 1I) and the additional conductive contact structures 156 in electrical communication with the first conductive lines 138A may be in electrical communication with the vertically lower (e.g., in the Z-direction) transistor structures 160.

The additional conductive contact structures 156 in electrical communication with a conductive line 138 may be horizontally aligned (e.g., in the X-direction) with one another. In some embodiments, the additional conductive contact structures 156 are located within horizontal boundaries (e.g., in the X-direction) of the conductive lines 138 contacted by the respective additional conductive contact structures 156. In some embodiments, the additional conductive contact structures 156 are horizontally aligned (e.g., in the X-direction) with the conductive contact structures 136 and may be located within horizontal boundaries (e.g., in the X-direction) of the conductive contact structures 136.

The additional conductive contact structures 156 may individually be formed of and include conductive material, such as one or more of the materials described above with reference to the conductive material 118 of the conductive structures 122. In some embodiments, the additional conductive contact structures 156 individually comprise substantially the same material composition as the conductive contact structures 136. In some embodiments, the additional conductive contact structures 156 individually comprise tungsten.

After forming the additional conductive contact structures 156, the microelectronic device structure assembly 150 may be exposed to a chemical mechanical planarization process to remove conductive material from vertically uppermost surfaces (e.g., in the Z-direction) of the microelectronic device structure assembly 150, such as from upper surfaces of the eighth insulative material 152.

FIG. 10 is a simplified, partial cross-sectional view of the microelectronic device structure assembly 150 at a processing stage subsequent to that illustrated in FIG. 1L through FIG. 1N. The cross-section of FIG. 10 is taken through the same plane as that illustrated in FIG. 1M, but at a subsequent processing stage than that illustrated and described with reference to FIG. 1M.

With reference to FIG. 10, after forming the additional conductive contact structures 156, a tenth insulative material 158 may be formed over surfaces of the microelectronic device structure assembly 150, conductive pad structures 161 (e.g., conductive interconnect structures, conductive connector structures, conductive redistribution structures), may individually be formed in electrical communication with the additional conductive contact structures 156, and additional portions of the tenth insulative material 158 may be formed over the conductive pad structures 161.

As described in further detail herein, the conductive pad structures 161 may be configured to electrically connect the additional conductive contact structures 156 to an electrode of a storage device (e.g., storage devices 176 (FIG. 1U, FIG. 1V)) and to provide a sufficient area for electrically connecting (e.g., landing) the electrode of the storage device during formation thereof.

After forming the tenth insulative material 158 and the conductive pad structures 161, a stack structure 162 comprising a vertically alternating (e.g., in the Z-direction) sequence of insulative structures 164 and sacrificial structures 166. The vertically alternating sequence of insulative structures 164 and sacrificial structures 166 may be arranged in pairs, each pair comprising an insulative structure 164 and a sacrificial structure 166 vertically neighboring (e.g., in the Z-direction) the insulative structure 164. In some embodiments, one of the sacrificial structures 166 vertically overlies (e.g., in the Z-direction) and directly contacts the tenth insulative material 158 and the additional conductive contact structures 156.

The insulative structures 164 may be formed of and include insulative material, such as one or more of the materials described above with reference to the first insulative material 103. In some embodiments, the insulative structures 164 comprise silicon dioxide.

The sacrificial structures 166 may be formed of and include at least one material (e.g., at least one insulative material) that may be selectively removed relative to the insulative structures 164. The sacrificial structures 166 may be selectively etchable relative to the insulative structures 164 during common (e.g., collective, mutual) exposure to a first etchant; and the insulative structures 164 may be selectively etchable to the sacrificial structures 166 during common exposure to a second, different etchant. By way of non-limiting example, depending on the material composition of the insulative structures 164, the sacrificial structures 166 may be formed of and include one or more of at least one dielectric oxide material (e.g., one or more of AlOₓ, HfOₓ, NbOₓ, TiOₓ, ZrOₓ, TaOₓ, and a MgOₓ), at least one dielectric nitride material (e.g., SiN_{y}), at least one dielectric oxynitride material (e.g., SiOₓN_{y}), at least one dielectric oxycarbide material (e.g., SiOₓC_{y}), at least one hydrogenated dielectric oxycarbide material (e.g., SiCₓO_{y}H_{z}), at least one dielectric carboxynitride material (e.g., SiOₓC_{z}N_{y}), and at least one semiconductive material (e.g., polycrystalline silicon). In some embodiments, the sacrificial structures 166 individually comprise a dielectric nitride material, such as SiN_{y} (e.g., Si₃N₄). The sacrificial structures 166 may, for example, be selectively etchable relative to the insulative structures 164 during common exposure to a wet etchant comprising phosphoric acid (H₃PO₄).

The tenth insulative material 158 may be formed of and include insulative material, such as one or more of the materials described above with reference to the first insulative material 103. In some embodiments, the tenth insulative material 158 comprises silicon dioxide.

The conductive pad structures 161 may individually be formed of and include conductive material, such as one or more of the materials described above with reference to the additional conductive contact structures 156. In some embodiments, the conductive pad structures 161 individually comprise tungsten.

FIG. 1P and FIG. 1Q are simplified, partial cross-sectional views of the microelectronic device structure assembly 150 at a processing stage subsequent to that illustrated in FIG. 10. The cross-section of FIG. 1P is taken through the same plane as that illustrated in FIG. 10, but at a subsequent processing stage than that illustrated and described with reference to FIG. 10. The cross-section of FIG. 1Q is taken through the same plane as that illustrated in FIG. 1N, but at a subsequent processing stage than that illustrated and described with reference to FIG. 1N.

After forming the stack structure 162, openings 168 may be formed within the stack structure 162 to expose vertically uppermost (e.g., in the Z-direction) surfaces of the tenth insulative material 158. After forming the openings 168. The openings 168 may individually be formed directly vertically over (e.g., in the Z-direction) and within horizontal boundaries (e.g., in the X-direction, in the Y-direction) of the conductive pad structures 161.

The openings 168 may individually be formed by, for example, sequentially removing portions of the insulative structures 164 and the sacrificial structures 166 through, for example, a mask material. The portions of the insulative structures 164 and the sacrificial structures 166 may be removed by exposing the insulative structures 164 and the sacrificial structures 166 to one or more dry etchants, such as one or more of CF₄ (e.g., a mixture of CF₄, O₂, and N₂), CHF₃, CCl₂F₂, NF₃ (e.g., a mixture of NF₃ and O₂), and SF₆.

In some embodiments, exposed portions of the tenth insulative material 158 may be removed through at least some of the openings 168 to expose the vertically underlying (e.g., in the Z-direction) conductive pad structure 161. By way of non-limiting example, in some embodiments, the exposed portions of the tenth insulative material 158 may be removed from alternating pairs of the openings 168. In some embodiments, the conductive pad structures 161 in electrical communication with the first additional conductive contact structures 156A may be exposed through the openings, while the conductive pad structures 161 in electrical communication with the second additional conductive contact structures 156B are not exposed through the openings 168. By way of non-limiting example, a mask material may be formed over the conductive pad structures 161 in electrical communication with the second additional conductive contact structures 156B and the tenth insulative material 158 vertically over the conductive pad structures 161 in electrical communication with the first additional conductive contact structures 156A may be removed to expose the conductive pad structures 161. After exposing the conductive pad structures 161, the mask material may be removed.

With collective reference to FIG. 1P and FIG. 1Q, in some embodiments, the pairs of openings 168 exposing the conductive pad structures 161 in electrical communication with the second additional conductive contact structures 156B may be horizontally spaced from one another in a first horizontal direction (e.g., in the Y-direction) and in a second horizontal direction (e.g., in the X-direction).

With continued reference to FIG. 1P and FIG. 1Q, after forming the openings 168 and exposing some of the conductive pad structures 161 (e.g., one half of the conductive pad structures 161, such as the conductive pad structures 161 in electrical communication with the second additional conductive contact structures 156B), portions of the sacrificial structures 166 may be selectively removed relative to the insulative structures 164 and the tenth insulative material 158. By way of non-limiting example, the portions of the sacrificial structures 166 may be selectively removed relative to the insulative structures 164 and the tenth insulative material 158 by exposing the sacrificial structures 166 to a wet etchant, such as phosphoric acid.

In some embodiments, the size and location of the openings 168 corresponds to the size and shape of the active regions 105 (FIG. 1L). However, the disclosure is not so limited, and the size and shape of the openings 168 may be different than that described. Although FIG. 1P and FIG. 1Q illustrate a various amount of the sacrificial structures 166 remaining, the disclosure is not so limited. In other embodiments, the sacrificial structures 166 may be more completely selectively removed (e.g., substantially completely removed) and replaced with an insulative material.

FIG. 1R and FIG. 1S are simplified, partial cross-sectional views of the microelectronic device structure assembly 150 at a processing stage subsequent that illustrated in FIG. 1P and FIG. 1Q. FIG. 1R is taken through the same plane as that illustrated in FIG. 1P, but at a subsequent processing stage than that illustrated and described with reference to FIG. 1P. FIG. 1S is taken through the same plane as that illustrated in FIG. 1Q, but at a subsequent processing stage than that illustrated and described with reference to FIG. 1Q.

After selectively removing the portions of the sacrificial structures 166, a first electrode material 170 may be formed on surfaces of the insulative structures 164 and the remaining portions of the sacrificial structures 166. After forming the first electrode material 170, a dielectric material 172 (also referred to as a “capacitor dielectric” material) may be formed on surfaces of the first electrode material 170. In some embodiments, the first electrode material 170 and the dielectric material 172 are formed by deposition, such as by ALD.

In some embodiments, the first electrode material 170 is formed in contact with one half of the conductive pad structures 161, such as the conductive pad structures 161 in electrical communication with the second additional conductive contact structures 156B. The first electrode material 170 may be electrically insulated from the other one half of the conductive pad structures 161 (e.g., such as by means of the tenth insulative material 158), such as the conductive pad structures 161 in electrical communication with the first additional conductive contact structures 156A.

The first electrode material 170 may be formed of and include conductive material such as, for example, one or more of a metal (e.g., tungsten, titanium, nickel, platinum, rhodium, ruthenium, aluminum, copper, molybdenum, iridium, silver, gold), a metal alloy, a metal-containing material (e.g., metal nitrides, metal silicides, metal carbides, metal oxides), a material including at least one of titanium nitride (TiN), tantalum nitride (TaN), tungsten nitride (WN), titanium aluminum nitride (TiAIN), iridium oxide (IrOₓ), ruthenium oxide (RuOₓ), alloys thereof, a conductively doped semiconductor material (e.g., conductively doped silicon, conductively doped germanium, conductively doped silicon germanium), polysilicon, and other materials exhibiting electrical conductivity. In some embodiments, the first electrode material 170 comprises titanium nitride.

The dielectric material 172 may be formed of and include one or more of silicon dioxide (SiO₂), silicon nitride (Si₃N₄), polyimide, titanium dioxide (TiO₂), tantalum oxide (Ta₂O₅), aluminum oxide (Al₂O₃), an oxide-nitride-oxide material (e.g., silicon dioxide-silicon nitride-silicon dioxide), strontium titanate (SrTiO₃) (STO), barium titanate (BaTiO₃), hafnium oxide (HfO₂), zirconium oxide (ZrO₂), a ferroelectric material (e.g., ferroelectric hafnium oxide, ferroelectric zirconium oxide, lead zirconate titanate (PZT)), and a high-k dielectric material.

FIG. 1T through FIG. 1V are a simplified, partial top-down view (FIG. 1T) and simplified, partial cross-sectional views (FIG. 1U and FIG. 1V) of the microelectronic device structure assembly 150 at a processing stage subsequent that illustrated in FIG. 1R and FIG. 1S. FIG. 1U is taken through section line U-U of FIG. 1T and FIG. 1V is taken through section line V-V of FIG. 1T. The processing stage of FIG. 1T through FIG. 1V may facilitate the formation of a microelectronic device 192.

After forming the first electrode material 170 and the dielectric material 172, portions of the first electrode material 170 and the dielectric material 172 may be removed from surfaces of the tenth insulative material 158 to expose a portion of the tenth insulative material 158 through the openings 168 (FIG. 1R, FIG. 1S); and exposed portions of the tenth insulative material 158 may be removed through the openings 168 to expose portions of the vertically underlying (e.g., in the Z-direction) conductive pad structures 161 that are not in electrical communication with the first electrode material 170, such as the conductive pad structures 161 in electrical communication with the first additional conductive contact structures 156A. In some embodiments, one half of the conductive pad structures 161 (e.g., the other half of the conductive pad structures 161 that are not exposed prior to formation of the first electrode material 170) are exposed through the first electrode material 170 and the dielectric material 172. In some embodiments, such conductive pad structures 161 may not be in electrical communication with the first electrode material 170.

After exposing the conductive pad structures 161 in electrical communication with the first additional conductive contact structures 156A, a second electrode material 174 may be formed within the openings 168 (FIG. 1R, FIG. 1S) and on surfaces of the dielectric material 172 to form storage devices 176. Each of the storage devices 176 individually comprises the first electrode material 170, the second electrode material 174, and the dielectric material 172 between the first electrode material 170 and the second electrode material 174.

The second electrode material 174 of one half of the storage devices 176 may individually be in contact with a conductive pad structure 161, such as a conductive pad structures 161 in electrical communication with one of the first additional conductive contact structures 156A. The second electrode material 174 of the other one half of the storage devices 176 may not be in electrical communication with a conductive pad structure 161.

The second electrode material 174 may be formed of and include conductive material, such as one or more of the materials described above with reference to the first electrode material 170. In some embodiments, the second electrode material 174 comprises substantially the same material composition as the first electrode material 170.

With reference to FIG. 1T, the storage devices 176 may be located vertically over (e.g., in the Z-direction) and within horizontal boundaries (e.g., in the X-direction, in the Y-direction) of the transistor structures 160 with which the storage device 176 is configured to be in electrical communication (e.g., such as through a first additional conductive contact structure 156A and a second additional conductive contact structure 156B). In FIG. 1T, for clarity and case of understanding the description, only one of the storage devices 176 is illustrated. However, it will be understood that the microelectronic device structure assembly 150 includes multiple storage device 176, such as one storage structure 176 for every pair of upper transistor structures 160A and lower transistor structures 160B. A cross-sectional shape of the storage devices 176 may be substantially rectangular, square, circular, or elliptical. In other embodiments, the cross-sectional shape of the storage devices 176 is substantially rectangular or square.

With collective reference to FIG. 1T, FIG. 1U, and FIG. 1V, the transistor structures 160 and the storage devices 176 may form memory cells 190, illustrated by way of dashed boxes 190, of the microelectronic device 192. Each of the memory cells 190 may individually include a lower transistor structure 160 in electrical communication with a storage device 176 vertically overlying (e.g., in the Z-direction) the lower transistor structure 160 by means of an additional conductive contact structure 156 (e.g., one of the first additional conductive contact structures 156A or the second additional conductive contact structures 156B); and an upper transistor structure 160A in electrical communication with the storage device 176 vertically overlying the upper transistor structure 160A by means of another one of the additional conductive contact structures 156 (e.g., the other of the first additional conductive contact structures 156A or the second additional conductive contact structures 156B).

In some embodiments, each memory cell 190 includes a first transistor structure 160 (e.g., one of a lower transistor structure 160B and an upper transistor structure 160A) in electrical communication with a first conductive line 138A (e.g., by means of one of the conductive contact structures 136) and a second transistor structure 160 (e.g., the other of the lower transistor structure 160B and the upper transistor structure 160A) in electrical communication with a second conductive line 138B (e.g., by means of one of the conductive contact structures 136) directly horizontally neighboring (e.g., in the X-direction) the first conducive line 138A.

Each of the memory cells 190 may include multiple (e.g., two or more, such as two) of the transistor structures 160. In some embodiments, each of the memory cells 190 comprises two of the transistor structures 160 in operable communication with (e.g., electrical communication with) a storage device 176. In some embodiments, each of the transistor structures 160 individually includes multiple vertical levels of channel regions 125. In some such embodiments, the memory cells 190 may be referred to as so-called two transistor-one capacitor (2T-1C) memory cells. The transistor structures 160 of a single memory cell 190 may be vertically stacked (e.g., in the Z-direction) with respect to one another. By way of non-limiting example, the memory cells 190 may individually comprise two transistor structures 160 vertically spaced (e.g., in the Z-direction) from one another. A first one of the transistor structures 160 may be closer to the storage device 176 than a second one of the transistor structures 160; and the second one of the transistor structures 160 may be closer to the conductive line 138 than the first one of the transistor structures 160.

Forming the memory cells 190 to include the transistor structures 160 individually comprising multiple levels of channel regions 125 vertically spaced (e.g., in the Z-direction) from one another facilitates forming the memory cells 190 to include channel regions exhibiting a greater ion distribution and a larger channel length compared to conventional memory cells that do not include vertically stacked transistor structures. For example, vertically stacking the channel regions 125 of the same transistor structure 160 facilitates increasing the channel length of the transistor structure 160 without increasing a horizontal footprint (e.g., in the X-direction, in the Y-direction) of the transistor structure 160, facilitating an increased density of memory cells 190.

Forming the microelectronic device structure assembly 150 to include memory cells 190 comprising multiple (e.g., two) transistor structures 160 vertically spaced (e.g., in the Z-direction) from one another may facilitate forming the memory cells 190 to exhibit a reduced read disturb compared to conventional microelectronic devices including 1T-1C memory cells, without increasing a horizontal area (e.g., in the X-direction, in the Y-direction) occupied by the memory cells 190. In addition, forming the storage devices 176 vertically over (e.g., in the Z-direction) the transistor structures 160 facilitates forming the storage devices 176 to exhibit a desired capacitance, which may be based at least in part, on the quantity of levels (and, thus, the height) of the storage devices 176. Accordingly, the capacitance of the storage devices 176 may be increased or decreased by respectively increasing or decreasing the number of levels of the first electrode material 170, the dielectric material 172, and the second electrode material 174 defining the storage devices 176. Accordingly, the capacitance of the storage devices 176 may be increased or decreased without increasing or decreasing the horizontal area occupied by the storage devices 176, and thus, the memory cells 190. In addition, because the memory cells 190 comprise 2T-1C memory cells, read operations of the memory cells 190 may not require sensing a reference voltage of a sense amplifier (e.g., a DVC2 sense amplifier reference voltage), reducing the processing and operating cost of the memory cells 190. In some embodiments, the memory cells 190 may be configured to provide an equivalent read signal compared to a conventional 1T-1C memory cell, but with a lower capacitance (e.g., of the storage device 176).

Although the transistor structures 160 have been described and illustrated as individually comprising multiple vertical levels of channel regions 125, the disclosure is not so limited. In other embodiments, the transistor structures 160 individually include only one level of a channel region 125 and the memory cells 190 include two transistor structures 160, each transistor structure 160 including a single channel region 125. The channel region 125 of each of the transistor structures 160 may be vertically spaced (e.g., in the Z-direction) from the channel region 125 of the other transistor structure 160.

Although the memory cells 190 have been described and illustrated as including two transistor structures 160, each transistor structure 160 being in electrical communication with a different one of the conductive lines 138 (e.g., by means of the different conductive contact structures 136), the disclosure is not so limited. In other embodiments, the memory cells 190 may include two transistor structures 160, each of the two transistor structures 160 in electrical communication with the same conductive line 138. In some such embodiments, the transistor structures 160 of a memory cell 190 may be referred to as including or being in electrical communication with a “shared” conductive line 190.

Thus, in accordance with some embodiments of the disclosure, a microelectronic device comprises a first transistor structure comprising multiple vertical levels of channel regions, a second transistor structure neighboring the first transistor structure and comprising additional multiple vertical levels of channel regions, a storage device vertically overlying the first transistor structure and the second transistor structure, a first conductive contact structure contacting the first transistor structure, and a second conductive contact structure contacting the second transistor structure.

Thus, in accordance with some embodiments of the disclosure, a memory device comprises an array of memory cells, each memory cell of the array of memory cells comprising a first transistor and a second transistor, and a capacitor vertically overlying the first transistor and the second transistor and in electrical communication with each of the first transistor and the second transistor. The memory device further comprises a first conductive line, and a second conductive line horizontally spaced from the first conductive line in a first horizontal direction, at least some of the memory cells of the array of memory cells configured to be in electrical communication with each of the first conductive line and the second conductive line.

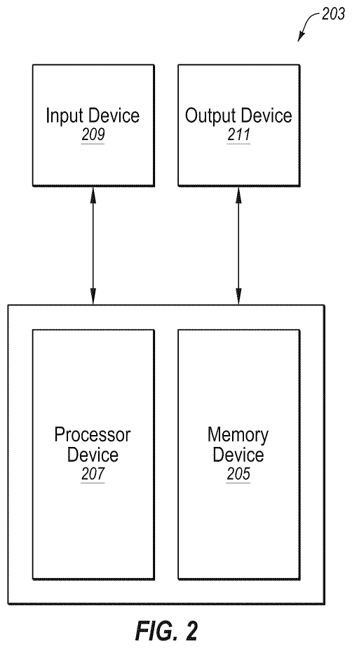

Microelectronic devices (e.g., the microelectronic device 192 (FIG. 1T, FIG. 1U, FIG. 1V)) of the disclosure may be included in embodiments of electronic systems of the disclosure. For example, FIG. 2 is a block diagram of an electronic system 203, in accordance with embodiments of the disclosure. The electronic system 203 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPAD® or SURFACE® tablet, an electronic book, a navigation device, etc. The electronic system 203 includes at least one memory device 205. The memory device 205 may include, for example, an embodiment of a microelectronic device previously described herein (e.g., the microelectronic device 192 previously described with reference to FIG. 1T, FIG. 1U, and FIG. 1V).

The electronic system 203 may further include at least one electronic signal processor device 207 (often referred to as a “microprocessor”). The electronic signal processor device 207 may, optionally, include an embodiment of one or more of a microelectronic device and a microelectronic device structure previously described herein. The electronic system 203 may further include one or more input devices 209 for inputting information into the electronic system 203 by a user, such as, for example, a mouse or other pointing device, a keyboard, a touchpad, a button, or a control panel. The electronic system 203 may further include one or more output devices 211 for outputting information (e.g., visual or audio output) to a user such as, for example, a monitor, a display, a printer, an audio output jack, a speaker, etc. In some embodiments, the input device 209 and the output device 211 may comprise a single touchscreen device that can be used both to input information to the electronic system 203 and to output visual information to a user. The input device 209 and the output device 211 may communicate electrically with one or more of the memory device 205 and the electronic signal processor device 207.

Thus, in at least some embodiments, an electronic device comprises an input device, an output device, a processor device operably coupled to the input device and the output device, and a memory device operably coupled to the processor device and comprising at least one microelectronic device. The at least one microelectronic device comprises a vertical stack of transistors comprising vertical pairs of transistors, the transistors of each of the vertical pairs of transistors vertically spaced from one another, and a stack structure comprising capacitors. Each capacitor structure comprises a first electrode configured to be in electrical communication with a first transistor of a vertical pair of transistors, and a second electrode configured to be in electrical communication with a second transistor of a vertical pair of transistors.

While certain illustrative embodiments have been described in connection with the figures, those of ordinary skill in the art will recognize and appreciate that embodiments encompassed by the disclosure are not limited to those embodiments explicitly shown and described herein. Rather, many additions, deletions, and modifications to the embodiments described herein may be made without departing from the scope of embodiments encompassed by the disclosure, such as those hereinafter claimed, including legal equivalents. In addition, features from one disclosed embodiment may be combined with features of another disclosed embodiment while still being encompassed within the scope of the disclosure.

What is claimed is:

1. A microelectronic device, comprising:
a first transistor structure comprising multiple vertical levels of channel regions;
a second transistor structure neighboring the first transistor structure and comprising additional multiple vertical levels of channel regions;
a storage device vertically overlying the first transistor structure and the second transistor structure;
a first conductive contact structure contacting the first transistor structure; and
a second conductive contact structure contacting the second transistor structure.

2. The microelectronic device of claim 1, further comprising a conductive line configured to be in electrical communication with the first transistor structure.

3. The microelectronic device of claim 2, further comprising an additional conductive line configured to be in electrical communication with the second transistor structure.

4. The microelectronic device of claim 1, wherein the second transistor structure is horizontally spaced from the first transistor structure in a first horizontal direction.

5. The microelectronic device of claim 4, further comprising:
a conductive line configured to be in electrical communication with the first transistor structure; and
an additional conductive line configured to be in electrical communication with the second transistor structure and horizontally spaced from the conductive line in a second horizontal direction.

6. The microelectronic device of claim 1, wherein the storage device exhibits a substantially rectangular cross-sectional shape.

7. The microelectronic device of claim 1, wherein the first conductive contact structure is horizontally offset from the second conductive contact structure.

8. The microelectronic device of claim 1, wherein the first conductive contact structure and the second conductive contact structure are configured to be in electrical communication with a same conductive line.

9. The microelectronic device of claim 1, wherein the multiple vertical levels of the channel regions of the first transistor structure are vertically offset from the additional multiple vertical levels of channel regions of the second transistor structure.

10. The microelectronic device of claim 1, wherein the first transistor structure is vertically aligned with the second transistor structure.

11. A memory device, comprising:
an array of memory cells, each memory cell of the array of memory cells comprising:
a first transistor and a second transistor; and
a capacitor vertically overlying the first transistor and the second transistor and in electrical communication with each of the first transistor and the second transistor; and
a first conductive line; and
a second conductive line horizontally spaced from the first conductive line in a first horizontal direction, at least some of the memory cells of the array of memory cells configured to be in electrical communication with each of the first conductive line and the second conductive line.

12. The memory device of claim 11, where each of the first transistor and the second transistor individually comprises multiple vertical levels of channel regions.

13. The memory device of claim 11, wherein:
the first conductive line is located within horizontal boundaries of the first transistor; and
the second conductive line is located within horizontal boundaries of the second transistor.

14. The memory device of claim 11, wherein the first transistor is vertically spaced from the second transistor.

15. The memory device of claim 11, further comprising:
a first conductive contact structure electrically connecting the first conductive line to the first transistor; and
a second conductive contact structure electrically connecting the second conductive line to the second transistor.

16. The memory device of claim 15, wherein:
the first conductive contact structure is horizontally spaced from the second conductive contact structure in the first horizontal direction; and
the first conductive contact structure is horizontally aligned with the second conductive contact structure in a second horizontal direction.

17. The memory device of claim 11, wherein the capacitor comprises multiple vertical levels of a first electrode material, a second electrode material, and a dielectric material between the first electrode material and the second electrode material.

18. An electronic system, comprising:
an input device;
an output device;
a processor device operably coupled to the input device and the output device; and
a memory device operably coupled to the processor device and comprising at least one microelectronic device, the at least one microelectronic device comprising:
a vertical stack of transistors comprising vertical pairs of transistors, the transistors of each of the vertical pairs of transistors vertically spaced from one another; and
a stack structure comprising capacitors, each capacitor comprising:
a first electrode configured to be in electrical communication with a first transistor of a vertical pair of transistors; and
a second electrode configured to be in electrical communication with a second transistor of a vertical pair of transistors.

19. The electronic system of claim 18, each transistor of the vertical pairs of transistors comprises vertically spaced channel regions.

20. The electronic system of claim 18, wherein:
a first transistor of one of the vertical pairs of transistors is in electrical communication with a first conductive line; and
a second transistor of the one of the vertical pairs of transistors is in electrical communication with a second conductive line.
